(19) United States
(12) Patent Application Publication
(10) Pub. No.: US 2026/0123445 A1
(43) Pub. Date: Apr. 30, 2026

(54) SEMICONDUCTOR DEVICE

(71) Applicant: SAMSUNG ELECTRONICS CO., LTD., Suwon-si (KR)

(72) Inventors: Han Seong KIM, Suwon-si (KR); Koung Min Ryu, Suwon-si (KR); Kang Sub Yim, Suwon-si (KR)

(73) Assignee: SAMSUNG ELECTRONICS CO., LTD., Suwon-si (KR)

(21) Appl. No.: 19/186,037

(22) Filed: Apr. 22, 2025

(30) Foreign Application Priority Data
Oct. 4, 2024 (KR) 10-2024-0134662

(51) Int. Cl. H01L 23/544; H10D 30/00; H10D 30/01; H10D 30/43; H10D 62/10; H10D 62/13; H10D 84/01; H10D 84/83

(52) U.S. Cl. CPC H10W 46/00; H10D 30/43; H10D 30/502; H10D 62/121; H10D 62/151; H10D 84/833; H10D 30/014; H10D 30/0191; H10D 84/0151; H10W 46/301

(57) ABSTRACT

A semiconductor device includes a substrate including a logic cell region and an alignment mark region, a first active pattern on the substrate and in the logic cell region, the first active pattern extending in a first horizontal direction, a second active pattern on the substrate and in the logic cell region, the second active pattern extending in the first horizontal direction and spaced apart from the first active pattern in a second horizontal direction that is different from the first horizontal direction, and a channel isolation layer on the substrate and in the logic cell region, the channel isolation layer extending in the first horizontal direction and isolating the first active pattern from the second active pattern in the second horizontal direction, where sidewalls of the channel isolation layer that are across the second horizontal direction contact the first active pattern and the second active pattern.

### CROSS-REFERENCE TO RELATED APPLICATION

This application is based on and claims priority to Korean Patent Application No. 10-2024-0134662, filed on Oct. 4, 2024, in the Korean Intellectual Property Office, the disclosure of which is incorporated by reference herein in its entirety.

### BACKGROUND

The present disclosure relates to a semiconductor device, and more particularly, to a semiconductor device including field effect transistor.

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device capable of improving the reliability of the region in which an alignment insulating structure is formed in an alignment mark region.

Additional aspects will be set forth in part in the description which follows and, in part, will be apparent from the description, or may be learned by practice of the presented embodiments.

According to an aspect of an example embodiment, a semiconductor device may include a substrate including a logic cell region and an alignment mark region, a first active pattern on the substrate and in the logic cell region, the first active pattern extending in a first horizontal direction, a second active pattern on the substrate and in the logic cell region, the second active pattern extending in the first horizontal direction and spaced apart from the first active pattern in a second horizontal direction that is different from the first horizontal direction, a channel isolation layer on the substrate and in the logic cell region, the channel isolation layer extending in the first horizontal direction and isolating the first active pattern from the second active pattern in the second horizontal direction, where sidewalls of the channel isolation layer that are across the second horizontal direction contact the first active pattern and the second active pattern, a first alignment structure on the substrate and in the alignment mark region, the first alignment structure extending in a third horizontal direction, a second alignment structure on the substrate and in the alignment mark region, the second alignment structure extending in the third horizontal direction and spaced apart from the first alignment structure in a fourth horizontal direction that is different from the third horizontal direction, a first alignment spacer contacting sidewalls of the first alignment structure that are across the fourth horizontal direction, a second alignment spacer contacting sidewalls of the second alignment structure that are across the fourth horizontal direction, an alignment trench between the first alignment spacer and the second alignment spacer, and an alignment insulating structure in the alignment trench, where the alignment insulating structure may include a first layer along sidewalls and a bottom surface of the alignment trench, the first layer contacting the first alignment spacer and the second alignment spacer, where a material of the first layer is the same as a material of the channel isolation layer, and an upper surface of the first layer is coplanar with an upper surface of the channel isolation layer, a second layer on the first layer and in the alignment trench, where a material of second layer is different from the material of the first layer, and a third layer filling a remaining portion of the alignment trench, where a material of the third layer is different from the material of the second layer.

According to an aspect of an example embodiment, a semiconductor device may include a substrate including a logic cell region and an alignment mark region, a channel isolation layer on the substrate and in the logic cell region, the channel isolation layer extending in a first horizontal direction, a plurality of first sub-nanosheets on the substrate and in the logic cell region, the plurality of first sub-nanosheets being spaced apart from each other in a vertical direction, where sidewalls of the plurality of first sub-nanosheets that are across a second horizontal direction different from the first horizontal direction contact the channel isolation layer, a plurality of second sub-nanosheets on the substrate and in the logic cell region, the plurality of second sub-nanosheets spaced apart from each other in the vertical direction, and spaced apart from the plurality of first sub-nanosheets in the second horizontal direction, where sidewalls of the plurality of second sub-nanosheets that are across the second horizontal direction contact the channel isolation layer, a gate electrode on the substrate and in the logic cell region, the gate electrode extending in the second horizontal direction and surrounding the plurality of first sub-nanosheets and the plurality of second sub-nanosheets, a first alignment gate electrode on the substrate and in the alignment mark region, the first alignment gate electrode extending in a third horizontal direction, a second alignment gate electrode on the substrate and in the alignment mark region, the second alignment gate electrode extending in the third horizontal direction and spaced apart from the first alignment gate electrode in a fourth horizontal direction that is different from the third horizontal direction, a first alignment spacer on sidewalls of the first alignment gate electrode that are across the fourth horizontal direction, a second alignment spacer on sidewalls of the second alignment gate electrode that are across the fourth horizontal direction, an alignment trench between the first alignment spacer and the second alignment spacer, and an alignment insulating structure in the alignment trench, where the alignment insulating structure may include a first layer along sidewalls and a bottom surface of the alignment trench, the first layer contacting each of the first alignment spacer and the second alignment spacer, where a material of the first layer the same as a material of the channel isolation layer, and an upper surface of the first layer is coplanar with an upper surface of the channel isolation layer, a second layer on the first layer and in the alignment trench, where a material of second layer is different from the material of the first layer, and a third layer filling a remaining portion of the alignment trench, where a material of the third layer is different from the material of the second layer.

According to an aspect of an example embodiment, a semiconductor device may include a substrate including a logic cell region and an alignment mark region, a first active pattern on the substrate and in the logic cell region, the first active pattern extending in a first horizontal direction, a second active pattern on the substrate and in the logic cell region, the second active pattern extending in the first horizontal direction and spaced apart from the first active pattern in a second horizontal direction that is different from the first horizontal direction, a channel isolation layer on the substrate and in the logic cell region, the channel isolation layer extending in the first horizontal direction and isolating the first active pattern from the second active pattern in the second horizontal direction, where sidewalls of the channel isolation layer that are across the second horizontal direction contact the first active pattern and the second active pattern, a plurality of first sub-nanosheets on the first active pattern and spaced apart from each other in a vertical direction, where sidewalls of the plurality of first sub-nanosheets that are across the second horizontal direction contact the channel isolation layer, a plurality of second sub-nanosheets on the second active pattern and spaced apart from each other in the vertical direction, the plurality of second sub-nanosheets spaced apart from the plurality of first sub-nanosheets in the second horizontal direction, where sidewalls of the plurality of second sub-nanosheets that are across the second horizontal direction contact the channel isolation layer, a gate electrode on the substrate and in the logic cell region, the gate electrode extending in the second horizontal direction and surrounding the plurality of first sub-nanosheets and the plurality of second sub-nanosheets, a first capping pattern contacting an upper surface of the gate electrode, the first capping pattern extending in the second horizontal direction, a first alignment gate electrode on the substrate and in the alignment mark region, the first alignment gate electrode extending in a third horizontal direction, a second alignment gate electrode on the substrate and in the alignment mark region, the second alignment gate electrode extending in the third horizontal direction and spaced apart from the first alignment gate electrode in a fourth horizontal direction that is different from the third horizontal direction, a first alignment spacer on sidewalls of the first alignment gate electrode that are across the fourth horizontal direction, a second alignment spacer on sidewalls of the second alignment gate electrode that are across the fourth horizontal direction, a first alignment capping pattern contacting an upper surface of the first alignment gate electrode, the first alignment capping pattern extending in the third horizontal direction, a second alignment capping pattern contacting an upper surface of the second alignment gate electrode, the second alignment capping pattern extending in the third horizontal direction, where the second alignment capping pattern is spaced apart from the first alignment capping pattern in the fourth horizontal direction, an alignment trench between the first alignment spacer and the second alignment spacer, and an alignment insulating structure in the alignment trench, where the alignment insulating structure may include a first layer along sidewalls and a bottom surface of the alignment trench, the first layer contacting the first alignment spacer and the second alignment spacer, where a material of the first layer the same as a material of the channel isolation layer, and an upper surface of the first layer is coplanar with an upper surface of the channel isolation layer, a second layer extending in the vertical direction along inner sidewalls of the first layer, where a material of second layer is different from the material of the first layer, and a third layer filling a remaining portion of the alignment trench, where a bottom surface of the third layer contacts the first layer, and a material of the third layer is different from the material of the second layer, and an upper surface of the first capping pattern, an upper surface of the first alignment capping pattern and an upper surface of the second alignment capping pattern may be coplanar with the upper surface of the first layer, an upper surface of the second layer, and an upper surface of the third layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a layout diagram illustrating a semiconductor device according to one or more embodiments;

FIG. 2 is a diagram illustrating the logic cell region of FIG. 1 according to one or more embodiments;

FIG. 3 is a cross-sectional view taken along line A-A′ of FIG. 2 according to one or more embodiments;

FIG. 4 is a cross-sectional view taken along line B-B′ of FIG. 2 according to one or more embodiments;

FIG. 5 is a cross-sectional view taken along line C-C′ of FIG. 2 according to one or more embodiments;

FIG. 6 is a diagram illustrating the alignment mark region of FIG. 1 according to one or more embodiments;

FIG. 7 is a cross-sectional view taken along line D-D′ of FIG. 6 according to one or more embodiments;

FIGS. 8 to 51 are diagrams illustrating a semiconductor device according to one or more embodiments;

FIG. 52 is a cross-sectional view illustrating a semiconductor device according to one or more embodiments;

FIG. 53 is a cross-sectional view illustrating a semiconductor device according to one or more embodiments;

FIG. 54 is a cross-sectional view illustrating a semiconductor device according to one or more embodiments;

FIG. 55 is a cross-sectional view illustrating a semiconductor device according to one or more embodiments; and

FIG. 56 is a cross-sectional view illustrating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In the following diagrams of a semiconductor device according to one or more embodiments, the semiconductor device is described as including, by way of example, a transistor (e.g., a Multi-Bridge Channel Field Effect Transistor (FET) (MBCFET™)) that includes nanosheets, but embodiments are not limited thereto. In one or more embodiments, the semiconductor device may include a fin-shaped transistor (FinFET) having a fin-shaped patterned channel region, a tunneling transistor (tunneling FET), or a three-dimensional (3D) transistor. Additionally, the semiconductor device according to one or more embodiments may include a bipolar junction transistor or a lateral double-diffused metal-oxide-semiconductor (LDMOS) transistor.

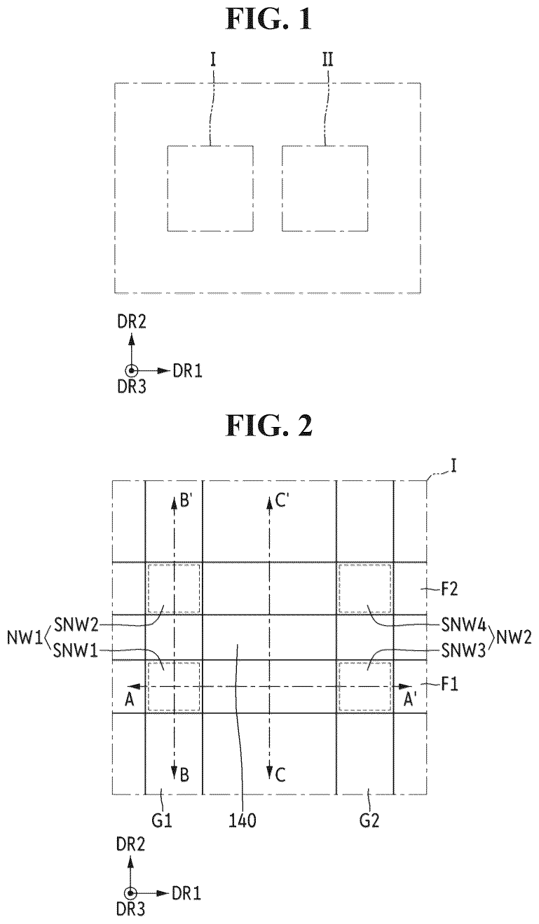

Hereinafter, a semiconductor device according to one or more embodiments of the present disclosure will be described with reference to FIGS. 1 to 7.

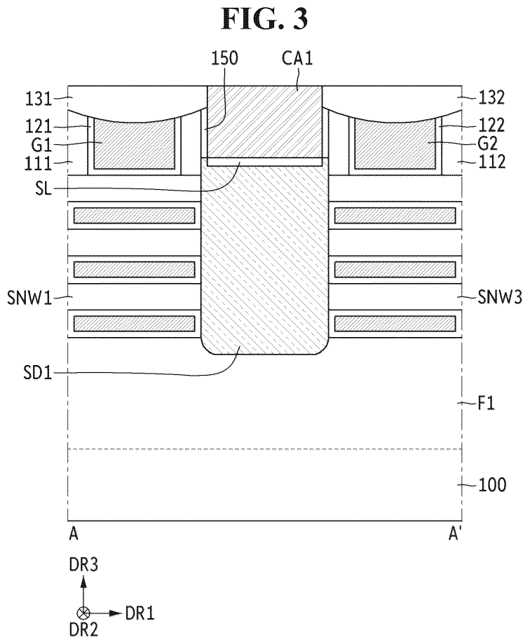

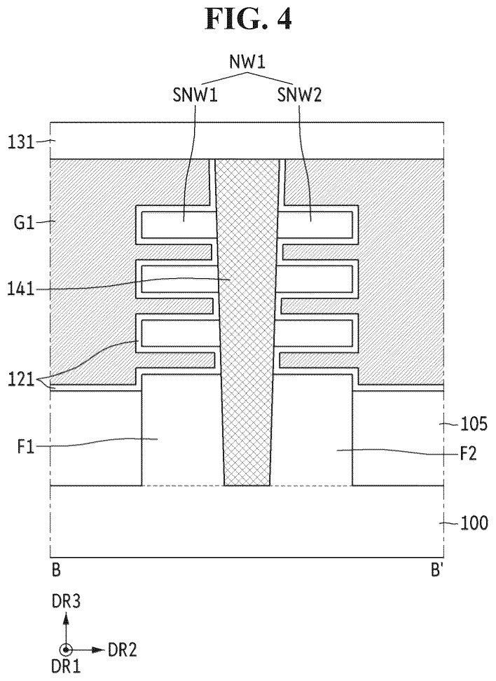

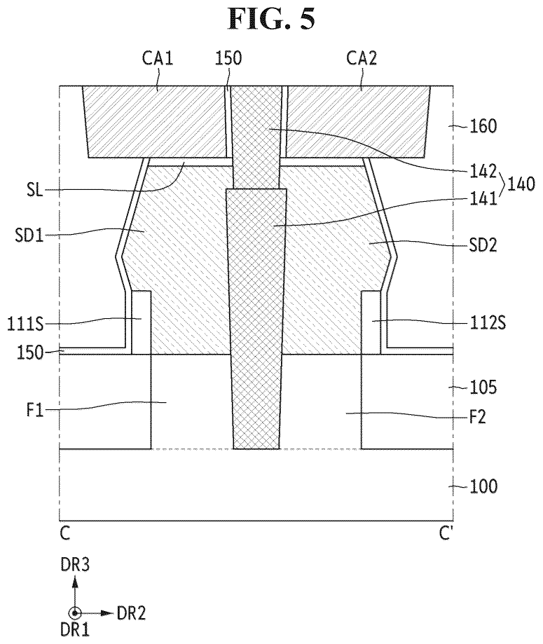

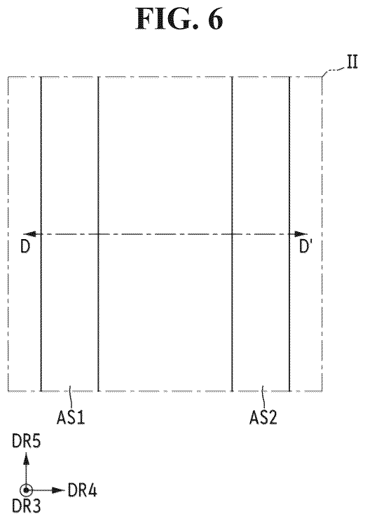

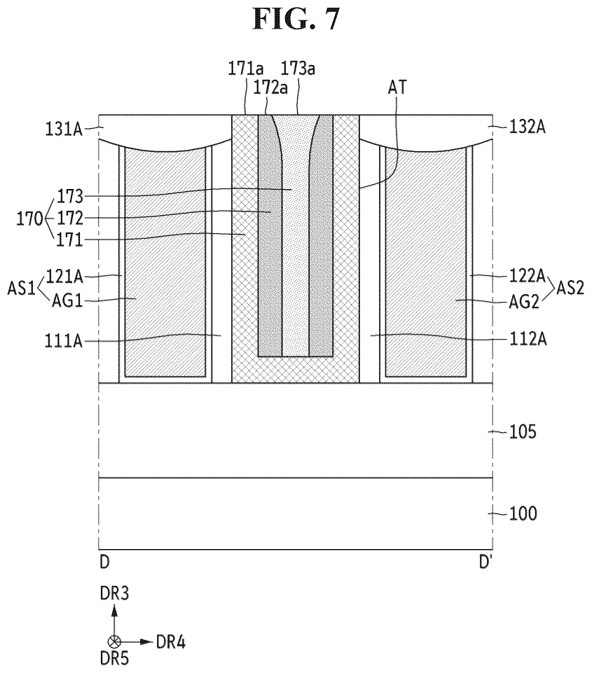

FIG. 1 is a layout diagram illustrating a semiconductor device according to one or more embodiments. FIG. 2 is a diagram illustrating the logic cell region of FIG. 1 according to one or more embodiments. FIG. 3 is a cross-sectional view taken along line A-A′ of FIG. 2 according to one or more embodiments. FIG. 4 is a cross-sectional view taken along line B-B′ of FIG. 2 according to one or more embodiments. FIG. 5 is a cross-sectional view taken along line C-C′ of FIG. 2 according to one or more embodiments. FIG. 6 is a diagram illustrating the alignment mark region of FIG. 1 according to one or more embodiments. FIG. 7 is a cross-sectional view taken along line D-D′ of FIG. 6 according to one or more embodiments.

Referring to FIGS. 1 to 7, a semiconductor device according to one or more embodiments may include a substrate 100, first and second active patterns F1, F2, a field insulating layer 105, first and plurality of second nanosheets NW1, NW2, first and second gate electrodes G1, G2, first and second gate spacers 111, 112, first and second gate insulating layers 121, 122, first and second capping patterns 131, 132, first and second source/drain regions SD1, SD2, a channel isolation layer 140, first and second source/drain spacers 111S, 112S, an etching stop layer 150, an interlayer insulating layer 160, first and second source/drain contacts CA1, CA2, a silicide layer SL, first and second alignment structures AS1, AS2, first and second alignment spacers 111A, 112A, first and second alignment capping patterns 131A, 132A, and an alignment insulating structure 170.

The substrate 100 may include a logic cell region I and an alignment mark region II. The substrate 100 may be a silicon substrate or silicon-on-insulator (SOI) substrate. Alternatively, the substrate 100 may include silicon germanium, silicon germanium on insulator (SGOI), indium antimonide, lead tellurium compounds, indium arsenide, indium phosphide, gallium arsenide, or gallium antimonide, but embodiments are not limited thereto.

Hereinafter, the first horizontal direction DR1, the second horizontal direction DR2, the third horizontal direction DR4, and the fourth horizontal direction DR5 may each be defined as directions parallel to the upper surface of the substrate 100. The second horizontal direction DR2 may be defined as a different direction from the first horizontal direction DR1. The fourth horizontal direction DR5 may be defined as a direction different from the third horizontal direction DR4. In one or more embodiments, the fourth horizontal direction DR5 may be the same direction as the second horizontal direction DR2, and the third horizontal direction DR4 may be the same direction as the first horizontal direction DR1. However, embodiments are not limited thereto. In one or more embodiments, the fourth horizontal direction DR5 may be the same direction as the first horizontal direction DR1, and the third horizontal direction DR4 may be in the same direction as the second horizontal direction DR2. The vertical direction DR3 may be defined as a direction perpendicular to each of the first horizontal direction DR1, the second horizontal direction DR2, the third horizontal direction DR4, and the fourth horizontal direction DR5. In other words, the vertical direction DR3 may be defined as a direction perpendicular to the upper surface of the substrate 100.

Each of the first active pattern F1 and the second active pattern F2 may extend in the first horizontal direction DR1 on the substrate 100 in the logic cell region I. The second active pattern F2 may be spaced apart from the first active pattern F1 in the second horizontal direction DR2. Each of the first and second active patterns F1, F2 may protrude in the vertical direction DR3 from the upper surface of the substrate 100. For example, each of the first and second active patterns F1, F2 may be part of the substrate 100, and may include an epitaxial layer grown from the substrate 100. For example, the first active pattern F1 and the second active pattern F2 may be isolated in the second horizontal direction DR2 by a channel isolation layer 140, which will be described later.

The field insulating layer 105 may be disposed on the upper surface of the substrate 100 in each of the logic cell region I and the alignment mark region II. The field insulating layer 105 may surround the sidewalls of each of the first and second active patterns F1, F2. For example, the upper surface of each of the first and second active patterns F1, F2 may protrude in the vertical direction DR3 beyond the upper surface of the field insulating layer 105. However, embodiments are not limited thereto. In one or more embodiments, the upper surface of each of the first and second active patterns F1, F2 may be coplanar with as the upper surface of the field insulating layer 105. The field insulating layer 105 may include, for example, an oxide layer, a nitride layer, an oxynitride layer, or a combination thereof.

The plurality of first nanosheets NW1 may be disposed on each of the first and second active patterns F1, F2. The plurality of first nanosheets NW1 may include a plurality of nanosheets stacked and spaced apart from each other in the vertical direction DR3 on each of the first and second active patterns F1, F2. For example, the plurality of first nanosheets NW1 may include a plurality of first sub-nanosheets SNW1 and a plurality of second sub-nanosheets SNW2. The plurality of first sub-nanosheets SNW1 may include a plurality of nanosheets stacked and spaced apart from each other in the vertical direction DR3 on the first active pattern F1. The plurality of second sub-nanosheets SNW2 may include a plurality of nanosheets stacked and spaced apart from each other in the vertical direction DR3 on the second active pattern F2. The plurality of second sub-nanosheets SNW2 may be spaced apart from the plurality of first sub-nanosheets SNW1 in the second horizontal direction DR2.

The plurality of second nanosheets NW2 may be disposed on each of the first and second active patterns F1, F2. The plurality of second nanosheets NW2 may include a plurality of nanosheets stacked and spaced apart from each other in the vertical direction DR3 on each of the first and second active patterns F1, F2. The plurality of second nanosheets NW2 may be spaced apart from the plurality of first nanosheets NW1 in the first horizontal direction DR1. For example, the plurality of second nanosheets NW2 may include a plurality of third sub-nanosheets SNW3 and a plurality of fourth sub-nanosheets SNW4. The plurality of third sub-nanosheets SNW3 may include a plurality of nanosheets stacked and spaced apart from each other in the vertical direction DR3 on the first active pattern F1. The plurality of fourth sub-nanosheets SNW4 may include a plurality of nanosheets stacked and spaced apart from each other in the vertical direction DR3 on the second active pattern F2. The plurality of fourth sub-nanosheets SNW4 may be spaced apart from the plurality of third sub-nanosheets SNW3 in the second horizontal direction DR2. The plurality of third sub-nanosheets SNW3 may be spaced apart from the plurality of first sub-nanosheets SNW1 in the first horizontal direction DR1. The plurality of fourth sub-nanosheets SNW4 may be spaced apart from the plurality of second sub-nanosheets SNW2 in the first horizontal direction DR1.

For example, the plurality of first sub-nanosheets SNW1 and the plurality of second sub-nanosheets SNW2 may be isolated from each other in the second horizontal direction DR2 by the channel isolation layer 140, which will be described later. For example, the plurality of third sub-nanosheets SNW3 and the plurality of fourth sub-nanosheets SNW4 may be isolated from each other in the second horizontal direction DR2 by the channel isolation layer 140, which will be described later. For example, each of the plurality of first nanosheets NW1 and the plurality of second nanosheets NW2 may include silicon (Si).

Each of the first and second gate electrodes G1, G2 may be disposed on the upper surface of the substrate 100 in the logic cell region I. The first gate electrode G1 may extend in the second horizontal direction DR2 on each of the first and second active patterns F1, F2. The first gate electrode G1 may surround the plurality of first nanosheets NW1. That is, the first gate electrode G1 may surround each of the plurality of first sub-nanosheets SNW1 and the plurality of second sub-nanosheets SNW2. The second gate electrode G2 may extend in the second horizontal direction DR2 on each of the first and second active patterns F1, F2. The second gate electrode G2 may be spaced apart from the first gate electrode G1 in the first horizontal direction DR1. The second gate electrode G2 may surround the plurality of second nanosheets NW2. That is, the second gate electrode G2 may surround each of the plurality of third sub-nanosheets SNW3 and the plurality of fourth sub-nanosheets SNW4. For example, each of the first and second gate electrodes G1, G2 may be isolated in the second horizontal direction DR2 by the channel isolation layer 140, which will be described later. However, embodiments are not limited thereto.

For example, each of the first and second gate electrodes G11, G12 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first and second gate electrodes G11, G12 may include a conductive metal oxide, a conductive metal oxynitride, or the like, and may include an oxidized form of the materials described above.

Each of the first and second gate spacers 111, 112 may be disposed on the upper surface of the substrate 100 in the logic cell region I. The first gate spacer 111 may be disposed on both sidewalls of the first gate electrode G1 that are across the first horizontal direction DR1. The first gate spacer 111 may extend in the second horizontal direction DR2 on the upper surface of the uppermost nanosheet of each of the first and plurality of second sub-nanosheets SNW1, SNW2 and on the field insulating layer 105. The second gate spacer 112 may be disposed on both sidewalls of the second gate electrode G2 that are across the first horizontal direction DR1. The second gate spacer 112 may extend in the second horizontal direction DR2 on the upper surface of the uppermost nanosheet of each of the third and plurality of fourth sub-nanosheets SNW3, SNW4 and on the field insulating layer 105. For example, each of the first and second gate spacers 111, 112 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), and combinations thereof. However, embodiments are not limited thereto.

The channel isolation layer 140 may be disposed on the upper surface of the substrate 100 in the logic cell region I. For example, the channel isolation layer 140 may extend in the first horizontal direction DR1 between the first active pattern F1 and the second active pattern F2. The channel isolation layer 140 may isolate the first active pattern F1 from the second active pattern F2 in the second horizontal direction DR2. Both sidewalls of the channel isolation layer 140 that are across the second horizontal direction DR2 may contact each of the first active pattern F1 and the second active pattern F2. For example, the channel isolation layer 140 may penetrate each of the first and plurality of second nanosheets NW1, NW2, and the first and second gate electrodes G1, G2 in the vertical direction DR3.

For example, the channel isolation layer 140 may be positioned to separate the plurality of first nanosheets NW1 into the plurality of first sub-nanosheets SNW1 and the plurality of second sub-nanosheets SNW2. Further, the channel isolation layer 140 may be positioned to separate the plurality of second nanosheets NW2 into the plurality of third sub-nanosheets SNW3 and the plurality of fourth sub-nanosheets SNW4. For example, both sidewalls of the channel isolation layer 140 that are across the second horizontal direction DR2 may contact each of the plurality of first sub-nanosheets SNW1 and the plurality of second sub-nanosheets SNW2. Additionally, both sidewalls of the channel isolation layer 140 that are across the second horizontal direction DR2 may contact each of the plurality of third sub-nanosheets SNW3 and the plurality of fourth sub-nanosheets SNW4. For example, the channel isolation layer 140 may isolate each of the first and second gate electrodes G1, G2 in the second horizontal direction DR2. However, embodiments are not limited thereto.

For example, the bottom surface of the channel isolation layer 140 may contact the upper surface of the substrate 100. For example, the bottom surface of the channel isolation layer 140 may be coplanar with as the bottom surface of each of the first and second active patterns F1, F2. However, embodiments are not limited thereto. For example, the channel isolation layer 140 may include silicon nitride (SiN), but embodiments are not limited thereto. In one or more embodiments, the channel isolation layer 140 may include silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), or silicon oxycarbide (SiOC). For example, the channel isolation layer 140 may include a different material from that of each of the first and second gate spacers 111, 112, but embodiments are not limited thereto.

For example, the channel isolation layer 140 may include a first portion 141 and a second portion 142. For example, the uppermost surface of the first portion 141 of the channel isolation layer 140 may be coplanar with as the upper surface of each of the first and second gate electrodes G1, G2. For example, the upper surface of the first portion 141 of the channel isolation layer 140 disposed between the first source/drain region SD1 and the second source/drain region SD2 described hereinafter may be formed lower than the upper surface of the first portion 141 of the channel isolation layer 140 that isolates the first gate electrode G1. In other words, the uppermost surface of the first portion 141 of the channel isolation layer 140 may be defined as the upper surface of the first portion 141 of the channel isolation layer 140 that isolates the first gate electrode G1.

For example, the second portion 142 of the channel isolation layer 140 may be disposed on the upper surface of the first portion 141 of the channel isolation layer 140. For example, the second portion 142 of the channel isolation layer 140 may be disposed on an upper surface of the first portion 141 of the channel isolation layer 140 disposed between the first source/drain region SD1 and the second source/drain region SD2. However, the second portion 142 of the channel isolation layer 140 may not be disposed on the upper surface of the first portion 141 of the channel isolation layer 140 that isolates the first gate electrode G1. Further, the second portion 142 of the channel isolation layer 140 is not disposed on the upper surface of the first portion 141 of the channel isolation layer 140 that isolates the second gate electrode G2. The bottom surface of the second portion 142 of the channel isolation layer 140 may contact the upper surface of the first portion 141.

For example, the upper surface of the second portion 142 of the channel isolation layer 140 may be formed higher than the upper surface of the first portion 141 of the channel isolation layer 140 that isolates the first gate electrode G1. In other words, the uppermost surface of the channel isolation layer 140 may be defined as the upper surface of the second portion 142 of the channel isolation layer 140. For example, the width in the second horizontal direction DR2 of the upper surface of the first portion 141 of the channel isolation layer 140 may be greater than the width in the second horizontal direction DR2 of the bottom surface of the first portion 141 of the channel isolation layer 140. For example, the width in the second horizontal direction DR2 of the upper surface of the second portion 142 of the channel isolation layer 140 may be greater than the width in the second horizontal direction DR2 of the bottom surface of the second portion 142 of the channel isolation layer 140.

For example, the width in the second horizontal direction DR2 of the upper surface of the first portion 141 of the channel isolation layer 140 may be greater than the width in the second horizontal direction DR2 of the bottom surface of the second portion 142 of the channel isolation layer 140. However, embodiments are not limited thereto. In one or more embodiments, the width in the second horizontal direction DR2 of the upper surface of the first portion 141 of the channel isolation layer 140 may be the equal to the width in the second horizontal direction DR2 of the bottom surface of the second portion 142 of the channel isolation layer 140. In one or more embodiments, the width in the second horizontal direction DR2 of the upper surface of the first portion 141 of the channel isolation layer 140 may be smaller than the width in the second horizontal direction DR2 of the bottom surface of the second portion 142 of the channel isolation layer 140. For example, the first portion 141 of the channel isolation layer 140 and the second portion 142 of the channel isolation layer 140 may include the same material. However, embodiments are not limited thereto.

Each of the first and second source/drain regions SD1, SD2 may be disposed on the upper surface of the substrate 100 in the logic cell region I. The first source/drain region SD1 may be disposed between the first gate electrode G1 and the second gate electrode G2 on the first active pattern F1. Both sidewalls of the first source/drain region SD1 that are across the first horizontal direction DR1 may contact each of the first and plurality of third sub-nanosheets SNW1, SNW3. The second source/drain region SD2 may be disposed between the first gate electrode G1 and the second gate electrode G2 on the second active pattern F2. The second source/drain region SD2 may be spaced apart from the first source/drain region SD1 in the second horizontal direction DR2. For example, the first and second source/drain regions SD1, SD2 may be isolated in the second horizontal direction DR2 by the channel isolation layer 140.

For example, the first source/drain region SD1 may contact a first sidewall of the channel isolation layer 140 in the second horizontal direction DR2, and the second source/drain region SD2 may contact a second sidewall of the channel isolation layer 140, which faces the first sidewall of the channel isolation layer 140 across the second horizontal direction DR2. For example, the upper surface of each of the first and second source/drain regions SD1, SD2 may be formed higher than the bottom surface of the second portion 142 of the channel isolation layer 140. For example, the upper surface of each of the first and second source/drain regions SD1, SD2 may be formed lower than the upper surface of the second portion 142 of the channel isolation layer 140.

Each of the first and second source/drain spacers 111S, 112S may be disposed on the upper surface of the substrate 100 in the logic cell region I. Each of the first and second source/drain spacers 111S, 112S may be disposed on the field insulating layer 105. For example, the bottom surface of each of the first and second source/drain spacers 111S, 112S may contact the upper surface of the field insulating layer 105. For example, the upper surface of each of the first and second source/drain spacers 111S, 112S may be formed lower than the upper surface of each of the first and second source/drain regions SD1, SD2. For example, one sidewall and the upper surface of the first source/drain spacer 111S may contact the first source/drain region SD1. For example, the first source/drain spacer 111S may be overlapped by at least a portion of the first source/drain region SD1 in the vertical direction DR3. For example, one sidewall and the upper surface of the second source/drain spacer 112S may contact the second source/drain region SD2. For example, the second source/drain spacer 112S may be overlapped by at least a portion of the second source/drain region SD2 in the vertical direction DR3. For example, each of the first and second source/drain spacers 111S, 112S may include the same material as each of the first and second gate spacers 111, 112.

Each of the first and second gate insulating layers 121, 122 may be disposed on the upper surface of the substrate 100 in the logic cell region I. The first gate insulating layer 121 may be disposed between the first gate electrode G1 and the first active pattern F1. The first gate insulating layer 121 may be disposed between the first gate electrode G1 and the second active pattern F2. The first gate insulating layer 121 may be disposed between the first gate electrode G1 and the field insulating layer 105. The first gate insulating layer 121 may be disposed between the first gate electrode G1 and the plurality of first sub-nanosheets SNW1. The first gate insulating layer 121 may be disposed between the first gate electrode G1 and the plurality of second sub-nanosheets SNW2. The first gate insulating layer 121 may be disposed between the first gate electrode G1 and the channel isolation layer 140. The first gate insulating layer 121 may be disposed between the first gate electrode G1 and the first gate spacer 111. The first gate insulating layer 121 may be disposed between the first gate electrode G1 and the first source/drain region SD1. The first gate insulating layer 121 may be disposed between the first gate electrode G1 and the second source/drain region SD2.

The second gate insulating layer 122 may be disposed between the second gate electrode G2 and the first active pattern F1. The second gate insulating layer 122 may be disposed between the second gate electrode G2 and the second active pattern F2. The second gate insulating layer 122 may be disposed between the second gate electrode G2 and the field insulating layer 105. The second gate insulating layer 122 may be disposed between the second gate electrode G2 and the plurality of third sub-nanosheets SNW3. The second gate insulating layer 122 may be disposed between the second gate electrode G2 and the plurality of fourth sub-nanosheets SNW4. The second gate insulating layer 122 may be disposed between the second gate electrode G2 and the channel isolation layer 140. The second gate insulating layer 122 may be disposed between the second gate electrode G2 and the second gate spacer 112. The second gate insulating layer 122 may be disposed between the second gate electrode G2 and the first source/drain region SD1. The second gate insulating layer 122 may be disposed between the second gate electrode G2 and the second source/drain region SD2.

Each of the first and second gate insulating layers 121, 122 may include at least one of silicon oxide, silicon oxynitride, silicon nitride, or a high-k dielectric material having a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to one or more embodiments may include a Negative Capacitance (NC) FET (NCFET) utilizing a negative capacitor. For example, each of the first and second gate insulating layers 121, 122 may include a ferroelectric material layer having ferroelectric properties and a paraelectric material layer having paraelectric properties.

The ferroelectric material layer may have a negative capacitance, while the paraelectric material layer may have a positive capacitance. For example, when two or more capacitors are connected in series and each of their capacitances has a positive value, the overall capacitance is reduced compared to the capacitance of each individual capacitor. On the other hand, if at least one of the capacitances of the two or more capacitors connected in series has a negative value, the overall capacitance may be greater than the absolute value of each individual capacitance while still being positive.

When the ferroelectric material layer having a negative capacitance and the paraelectric material layer having a positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

When the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain 3 to 8 at % (atomic %) of aluminum. Here, the ratio of the dopant may be a ratio of aluminum to the sum of hafnium and aluminum.

If the dopant is silicon (Si), the ferroelectric material layer may include 2 to 10 at % of silicon. If the dopant is yttrium (Y), the ferroelectric material layer may include 2 to 10 at % of yttrium. When the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness for exhibiting ferroelectric properties, the thickness of the ferroelectric material layer may vary depending on the specific ferroelectric material.

For example, each of the first and second gate insulating layers 121, 122 may include a single ferroelectric material layer. In another example, each of the first and second gate insulating layers 121, 122 may include a plurality of ferroelectric material layers spaced apart from each other. Each of the first and second gate insulating layers 121, 122 may have a stacked layer structure in which the plurality of ferroelectric material layers are alternately stacked with the plurality of paraelectric material layers.

The etching stop layer 150 may be disposed on the upper surface of the substrate 100 in the logic cell region I. The etching stop layer 150 may be disposed on the sidewalls that are across the first horizontal direction DR1 of each of the first and second gate spacers 111, 112. The etching stop layer 150 may be disposed on the upper surface of the field insulating layer 105. The etching stop layer 150 may be disposed on the sidewalls that are across the second horizontal direction DR2 of each of the first and second source/drain regions SD1, SD2. For example, the etching stop layer 150 may be disposed on both sidewalls in the second horizontal direction DR2 of the second portion 142 of the channel isolation layer 140 on the upper surfaces of each of the first and second source/drain regions SD1, SD2, but embodiments are not limited thereto. For example, the etching stop layer 150 may be conformally formed. The etching stop layer 150 may include at least one of, for example, aluminum oxide, aluminum nitride, hafnium oxide, zirconium oxide, silicon oxide, silicon nitride, silicon oxynitride, and a low-k dielectric material.

Each of the first and second capping patterns 131, 132 may be disposed on the upper surface of the substrate 100 in the logic cell region I. The first capping pattern 131 may extend in the second horizontal direction DR2 on the upper surface of each of the first gate spacer 111, the first gate insulating layer 121, and the first gate electrode G1. The first capping pattern 131 may contact the upper surface of each of the first gate spacer 111, the first gate insulating layer 121, and the first gate electrode G1. The second capping pattern 132 may extend in the second horizontal direction DR2 on the upper surface of each of the second gate spacer 112, the second gate insulating layer 122, and the second gate electrode G2. The second capping pattern 132 may contact the upper surface of each of the second gate spacer 112, the second gate insulating layer 122, and the second gate electrode G2.

For example, the bottom surface of the first capping pattern 131 may contact the upper surface of the first portion 141 of the channel isolation layer 140. For example, the bottom surfaces of each of the first and second capping patterns 131, 132 may contact the etching stop layer 150. However, embodiments are not limited thereto. For example, each of the first and second capping patterns 131, 132 may include at least one of silicon nitride (SiN), silicon oxynitride (SiON), silicon oxide (SiO₂), silicon carbonitride (SiCN), silicon oxycarbonitride (SiOCN), or combinations thereof. However, embodiments are not limited thereto.

The interlayer insulating layer 160 may be disposed on the upper surface of the substrate 100 in the logic cell region I. The interlayer insulating layer 160 may be disposed on the etching stop layer 150. The interlayer insulating layer 160 may cover each of the first and second source/drain regions SD1, SD2 on the field insulating layer 105. For example, the upper surface of the interlayer insulating layer 160 may be coplanar with as the upper surface of each of the first and second capping patterns 131, 132. The interlayer insulating layer 160 may include, for example, at least one of silicon oxide, silicon nitride, silicon oxynitride, and low-k dielectric materials.

Each of the first and second source/drain contacts CA1, CA2 may be disposed on the upper surface of the substrate 100 in the logic cell region I. Each of the first and second source/drain contacts CA1, CA2 may be disposed inside the interlayer insulating layer 160. For example, the first source/drain contact CA1 may be disposed on the upper surface of the first source/drain region SD1. The first source/drain contact CA1 may be electrically connected to the first source/drain region SD1. For example, the second source/drain contact CA2 may be disposed on the upper surface of the second source/drain region SD2. The second source/drain contact CA2 may be spaced apart from the first source/drain contact CA1 in the second horizontal direction DR2. The second source/drain contact CA2 may be electrically connected to the second source/drain region SD2. For example, the first and second source/drain contacts CA1, CA2 may be isolated in the second horizontal direction DR2 by the second portion 142 of the channel isolation layer 140. Each of the first and second source/drain contacts CA1, CA2 may include conductive materials.

The silicide layer SL may be disposed along the interface between the first source/drain region SD1 and the first source/drain contact CA1. Further, the silicide layer SL may be disposed along the interface between the second source/drain region SD2 and the second source/drain contact CA2. For example, the silicide layer SL may include a metal silicide material.

Each of the first and second alignment structures AS1, AS2 may be disposed on the upper surface of the substrate 100 in the alignment mark region II. For example, the first alignment structure AS1 may extend in the fourth horizontal direction DR5 on the upper surface of the field insulating layer 105. The second alignment structure AS2 may extend in the fourth horizontal direction DR5 on the upper surface of the field insulating layer 105. The second alignment structure AS2 may be spaced apart from the first alignment structure AS1 in the third horizontal direction DR4. In one or more embodiments, the fourth horizontal direction DR5, in which each of the first and second alignment structures AS1, AS2 extends, may be the same as the second horizontal direction DR2, in which each of the first and second gate electrodes G1, G2 extends. However, embodiments are not limited thereto. In one or more embodiments, the fourth horizontal direction DR5, in which each of the first and second alignment structures AS1, AS2 extends, may be the same as the first horizontal direction DR1, in which each of the first and second active patterns F1, F2 extends.

For example, the first alignment structure AS1 may include a first alignment gate insulating layer 121A and a first alignment gate electrode AG1. The first alignment gate insulating layer 121A may be disposed along the sidewalls and bottom surface of the first alignment gate electrode AG1. For example, the second alignment structure AS2 may include the second alignment gate insulating layer 122A and the second alignment gate electrode AG2. The second alignment gate insulating layer 122A may be disposed along the sidewalls and bottom surface of the second alignment gate electrode AG2. Each of the first and second alignment gate insulating layers 121A, 122A may contact the upper surface of the field insulating layer 105. For example, the upper surface of each of the first and second alignment gate electrodes AG1, AG2 may be coplanar with as the upper surface of each of the first and second gate electrodes G1, G2.

Each of the first and second alignment gate insulating layers 121A, 122A includes the same material as each of the first and second gate insulating layers 121, 122. This is because each of the first and second alignment gate insulating layers 121A, 122A and the first and second gate insulating layers 121, 122 may be formed through the same fabrication process. Further, each of the first and second alignment gate electrodes AG1, AG2 includes the same material as each of the first and second gate electrodes G1, G2. This is because the first and second alignment gate electrodes AG1, AG2 and the first and second gate electrodes G1, G2 may be formed through the same fabrication process.

Each of the first and second alignment spacers 111A, 112A may be disposed on the upper surface of the substrate 100 in the alignment mark region II. For example, the first alignment spacer 111A may be disposed on both sidewalls of the first alignment structure AS1 that are across the third horizontal direction DR4 on the upper surface of the field insulating layer 105. The first alignment spacers 111A may extend in the fourth horizontal direction DR5. The first alignment spacer 111A may contact both sidewalls of the first alignment structure AS1 that are across the third horizontal direction DR4. In other words, the first alignment spacer 111A may contact the first alignment gate insulating layer 121A. For example, the second alignment spacer 112A may be disposed on both sidewalls of the second alignment structure AS2 that are across the third horizontal direction DR4 on the upper surface of the field insulating layer 105. The second alignment spacers 112A may extend in the fourth horizontal direction DR5. The second alignment spacer 112A may contact both sidewalls of the second alignment structure AS2 that are across the third horizontal direction DR4. In other words, the second alignment spacer 112A may contact the second alignment gate insulating layer 122A. Each of the first and second alignment spacers 111A, 112A may include the same material as each of the first and second gate spacers 111, 112. This is because the first and second alignment spacers 111A, 112A and the first and second gate spacers 111, 112 may be formed through the same fabrication process.

Each of the first and second alignment capping patterns 131A, 132A may be disposed on the upper surface of the substrate 100 in the alignment mark region II. The first alignment capping pattern 131A may extend in the second horizontal direction DR2 on the upper surface of each of the first alignment spacer 111A and the first alignment structure AS1. The first alignment capping pattern 131A may contact the upper surface of each of the first alignment spacer 111A, the first alignment gate insulating layer 121A, and the first alignment gate electrode AG1. The second alignment capping pattern 132A may extend in the second horizontal direction DR2 on the upper surface of each of the second alignment spacer 112A and the second alignment structure AS2. The second alignment capping pattern 132A may contact the upper surface of each of the second alignment spacer 112A, the second alignment gate insulating layer 122A, and the second alignment gate electrode AG2. The second alignment capping pattern 132A may be spaced apart from the first alignment capping pattern 131A in the third horizontal direction DR4.

For example, the upper surface of each of the first and second alignment capping patterns 131A, 132A may be coplanar with as the upper surface of each of the first and second capping patterns 131, 132. Each of the first and second alignment capping patterns 131A, 132A may include the same material as each of the first and second capping patterns 131, 132. This is because the first and second alignment capping patterns 131A, 132A and the first and second capping patterns 131, 132 may be formed through the same fabrication process.

The alignment trench AT may be formed on the upper surface of the substrate 100 in the alignment mark region II. The alignment trench AT may be formed between the first alignment spacer 111A and the second alignment spacer 112A on the upper surface of the field insulating layer 105. For example, both sidewalls of the alignment trench AT that are across the third horizontal direction DR4 may be defined by the first and second alignment spacers 111A, 112A and the first and second alignment capping patterns 131A, 132A. Additionally, the bottom surface of the alignment trench AT may be defined by the upper surface of the field insulating layer 105.

The alignment insulating structure 170 may be disposed on the upper surface of the substrate 100 in the alignment mark region II. The alignment insulating structure 170 may be disposed inside the alignment trench AT. For example, the alignment insulating structure 170 may completely fill the inside of the alignment trench AT. For example, the upper surface of the alignment insulating structure 170 may be coplanar with as the upper surface of each of the first and second alignment capping patterns 131A, 132A, and the first and second capping patterns 131, 132. For example, the alignment insulating structure 170 may include a first layer 171, a second layer 172, and a third layer 173.

For example, the first layer 171 of the alignment insulating structure 170 may be disposed along the sidewalls and bottom surface of the alignment trench AT. For example, the first layer 171 of the alignment insulating structure 170 may be conformally formed. For example, the outer sidewalls in the third horizontal direction DR4 of the first layer 171 of the alignment insulating structure 170 may contact each of the first and second alignment spacers 111A, 112A. The bottom surface of the first layer 171 of the alignment insulating structure 170 may contact the upper surface of the field insulating layer 105. For example, the uppermost surface 171a of the first layer 171 of the alignment insulating structure 170 may be coplanar with as the upper surfaces of the first and second alignment capping patterns 131A, 132A, and the first and second capping patterns 131, 132, respectively. For example, the uppermost surface 171A of the first layer 171 of the alignment insulating structure 170 may be coplanar with as the uppermost surface of the channel isolation layer 140. That is, the uppermost surface 171A of the first layer 171 of the alignment insulating structure 170 may be coplanar with as the upper surface of the second portion 142 of the channel isolation layer 140. The first layer 171 of the alignment insulating structure 170 includes the same material as the second portion 142 of the channel isolation layer 140. This is because the first layer 171 of the alignment insulating structure 170 may be formed through the same fabrication process as the second portion 142 of the channel isolation layer 140. For example, the thickness of the first layer 171 of the alignment insulating structure 170 in the third horizontal direction DR4 may range from 10 nm to 30 nm.

For example, the second layer 172 of the alignment insulating structure 170 may extend in the vertical direction DR3 along the inner sidewalls in the third horizontal direction DR4 of the first layer 171 of the alignment insulating structure 170. For example, the second layer 172 of the alignment insulating structure 170 may contact the inner sidewalls that are across the third horizontal direction DR4 of the first layer 171 of the alignment insulating structure 170. For example, the bottom surface of the second layer 172 of the alignment insulating structure 170 may contact the first layer 171 of the alignment insulating structure 170. For example, the upper surface 172a of the second layer 172 of the alignment insulating structure 170 may be coplanar with as the uppermost surface 171a of the first layer 171 of the alignment insulating structure 170. For example, the width in the third horizontal direction DR4 of the upper surface 172a of the second layer 172 of the alignment insulating structure 170 may be greater than the width in the third horizontal direction DR4 of the bottom surface of the second layer 172 of the alignment insulating structure 170. For example, the upper sidewalls of the second layer 172 of the alignment insulating structure 170 that contact the third layer 173 of the alignment insulating structure 170 may have a sloped profile.

For example, the second layer 172 of the alignment insulating structure 170 may include a different material from that of the first layer 171 of the alignment insulating structure 170. For example, the second layer 172 of the alignment insulating structure 170 may include at least one of silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), and silicon carbon oxyhydride (SiCOH). For example, the thickness of the second layer 172 of the alignment insulating structure 170 in the third horizontal direction DR4 may range from 10 nm to 30 nm.

For example, the third layer 173 of the alignment insulating structure 170 may fill the remaining portion of the alignment trench AT between the second layer 172 of the alignment insulating structure 170. For example, both sidewalls in the third horizontal direction DR4 of the third layer 173 of the alignment insulating structure 170 may contact the second layer 172 of the alignment insulating structure 170. For example, the bottom surface of the third layer 173 of the alignment insulating structure 170 may contact the first layer 171 of the alignment insulating structure 170. For example, the upper surface 173a of the third layer 173 of the alignment insulating structure 170 may be coplanar with as each of the uppermost surface 171a of the first layer 171 of the alignment insulating structure 170 and the upper surface 172a of the second layer 172 of the alignment insulating structure 170. For example, the width in the third horizontal direction DR4 of the upper surface 173a of the third layer 173 of the alignment insulating structure 170 may be greater than the width in the third horizontal direction DR4 of the bottom surface of the third layer 173 of the alignment insulating structure 170. For example, the upper sidewalls of the third layer 173 of the alignment insulating structure 170 that contact the second layer 172 of the alignment insulating structure 170, may have a sloped profile.

For example, the third layer 173 of the alignment insulating structure 170 may include a different material from the second layer 172 of the alignment insulating structure 170. For example, the third layer 173 of the alignment insulating structure 170 may include silicon nitride (SiN). However, embodiments are not limited thereto. In one or more embodiments, the third layer 173 of the alignment insulating structure 170 may include at least one of silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), and silicon oxycarbide (SiOC). For example, the thickness of the third layer 173 of the alignment insulating structure 170 in the third horizontal direction DR4 may range from 10 nm to 30 nm.

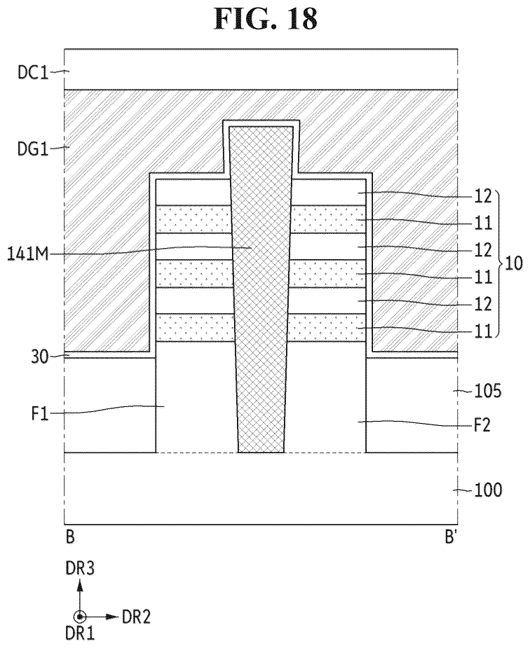

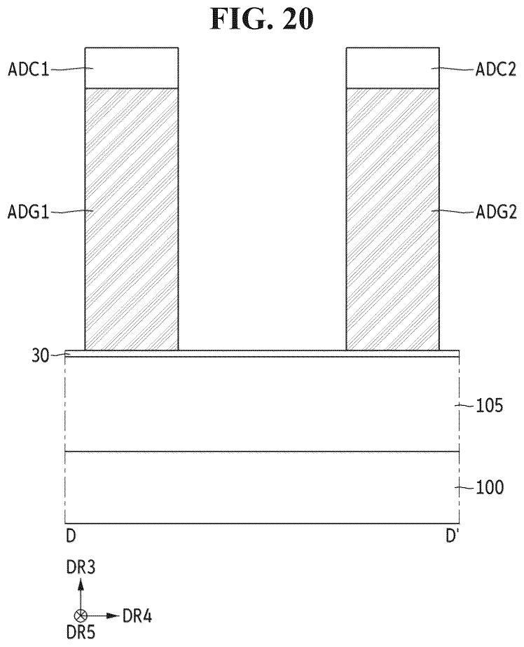

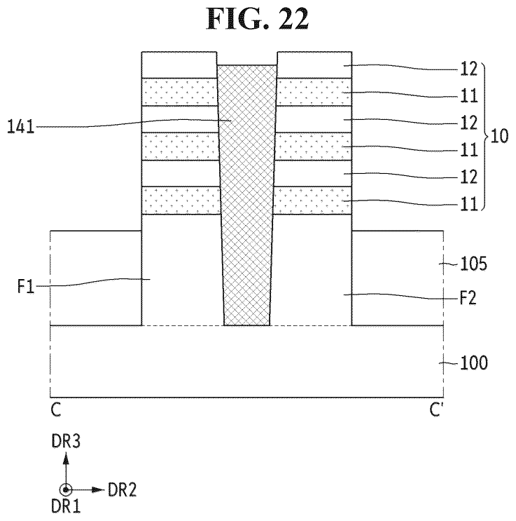

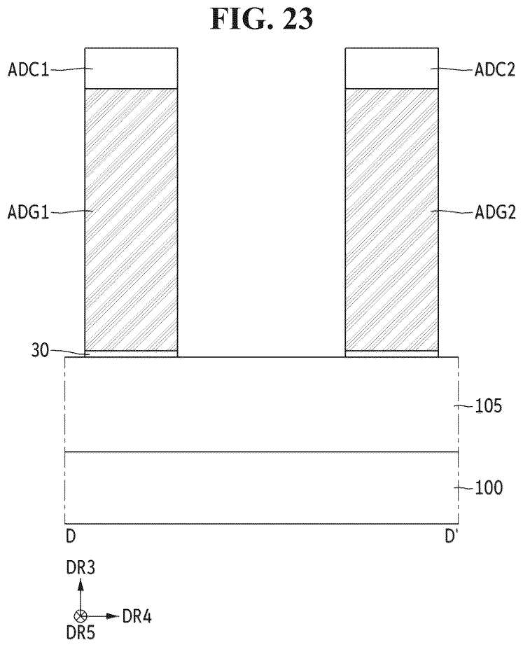

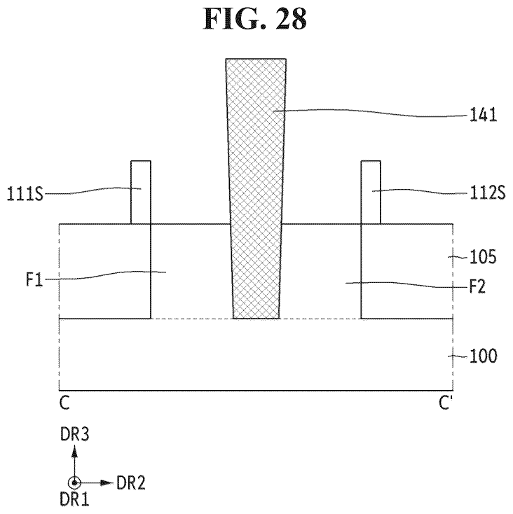

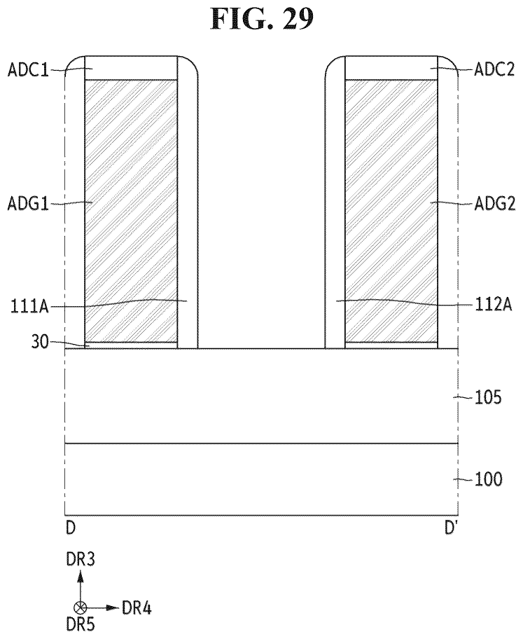

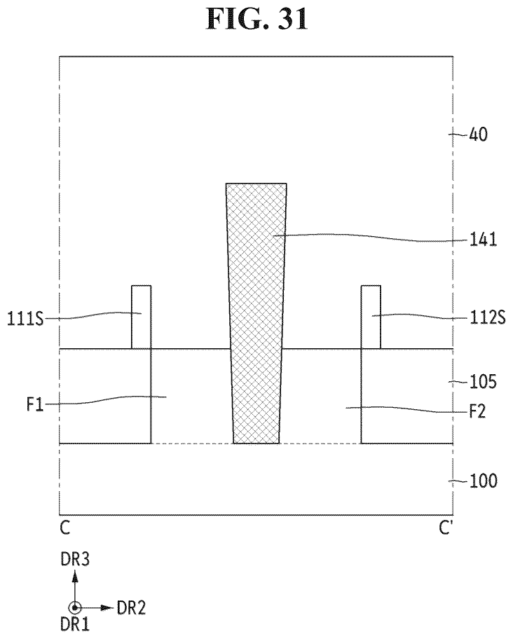

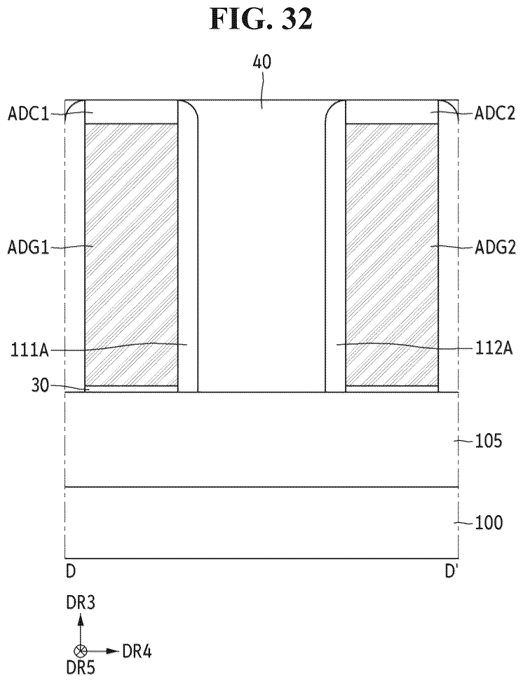

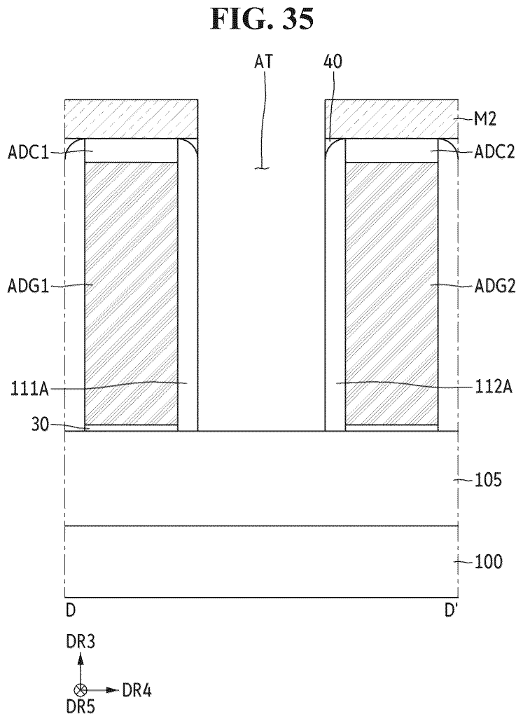

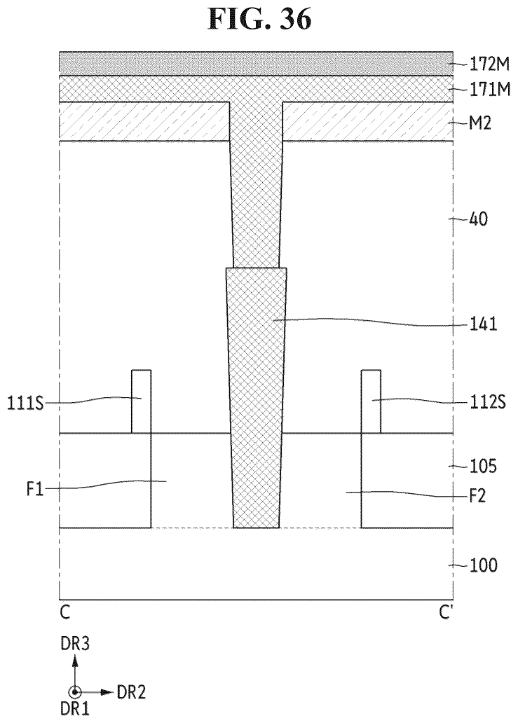

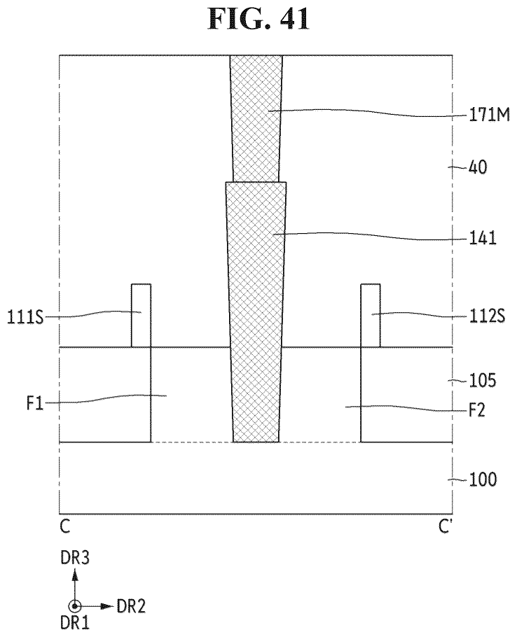

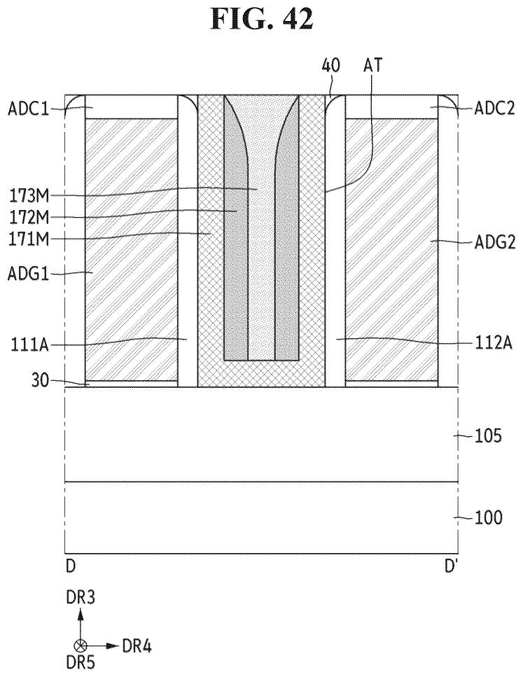

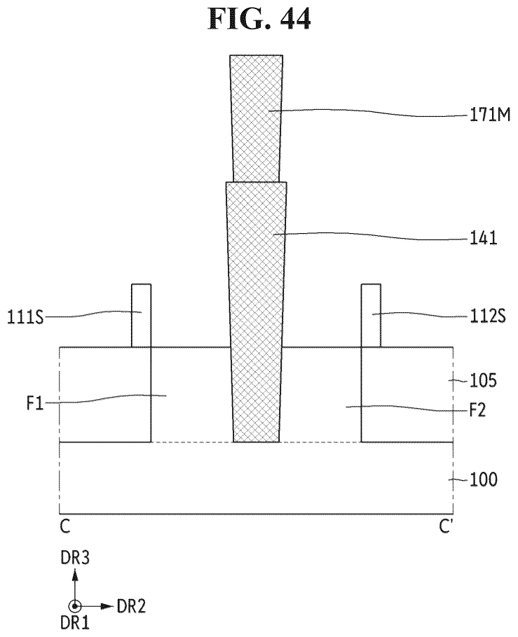

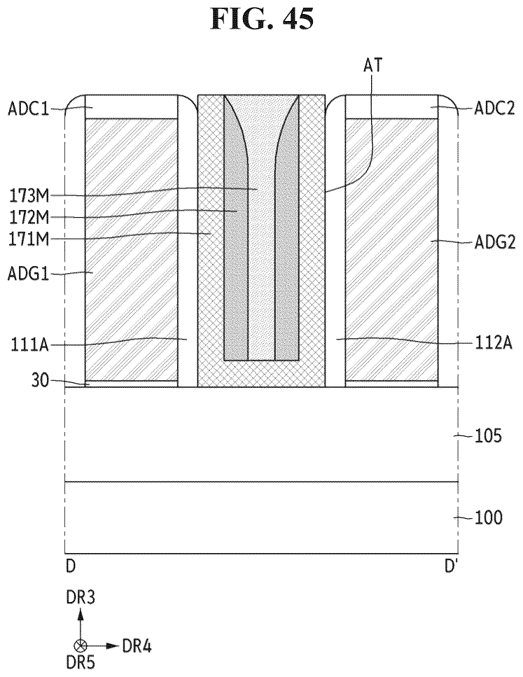

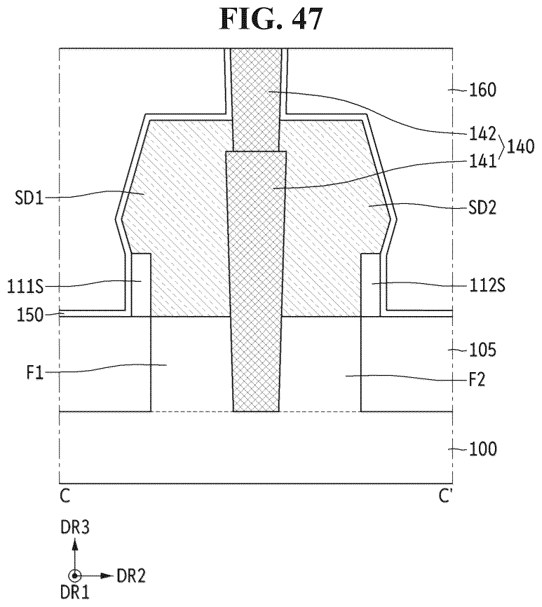

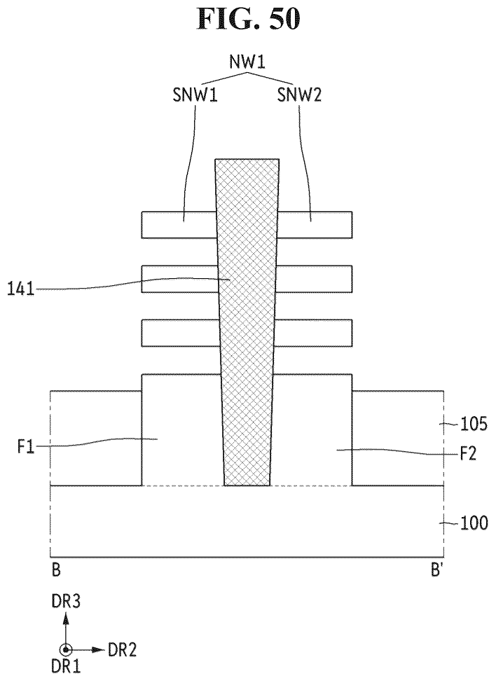

Hereinafter, the fabrication method of the semiconductor device according to one or more embodiments will be described with reference to FIGS. 1 to 51.

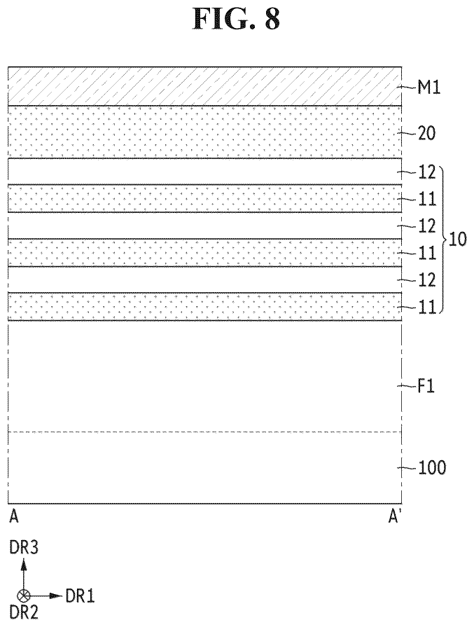

FIGS. 8 to 51 are intermediate stage diagrams for explaining the semiconductor device according to one or more embodiments.

Referring to FIGS. 8 to 10, a stacked structure 10 may be formed on the substrate 100. The stacked structure 10 may include a first semiconductor layer 11 and a second semiconductor layer 12 alternately stacked on the upper surface of the substrate 100. For example, the first semiconductor layer 11 may be formed on the lowermost surface of the stacked structure 10, and the second semiconductor layer 12 may be formed on the uppermost surface of the stacked structure 10. The first semiconductor layer 11 may include, for example, silicon germanium (SiGe). The second semiconductor layer 12 may include, for example, silicon (Si). Subsequently, a third semiconductor layer 20 may be formed on the upper surface of the stacked structure 10. For example, the thickness of the third semiconductor layer 20 in the vertical direction DR3 may be greater than the thickness of each of the first semiconductor layer 11 and the second semiconductor layer 12 in the vertical direction DR3. For example, the third semiconductor layer 20 may include, for example, silicon germanium (SiGe).

Subsequently, a first mask pattern M1 may be formed on the upper surface of the third semiconductor layer 20 in the logic cell region I. Subsequently, using the first mask pattern M1 as a mask, the third semiconductor layer 20 and the stacked structure 10 may be etched. While the third semiconductor layer 20 and the stacked structure 10 are being etched, a portion of the substrate 100 may also be etched. Through this etching process, the first active pattern F1 and the second active pattern F2 may be defined beneath the stacked structure 10 on the upper surface of the substrate 100. For example, each of the first and second active patterns F1, F2 may extend in the first horizontal direction DR1. The second active pattern F2 may be spaced apart from the first active pattern F1 in the second horizontal direction DR2. Additionally, the stacked structure 10 formed on the second active pattern F2 may be spaced apart from the stacked structure 10 formed on the first active pattern F1 in the second horizontal direction DR2. For example, the region between the first active pattern F1 and the second active pattern F2 may be defined as a first isolation trench T1. After this etching process is completed, the upper surface of the substrate 100 in the alignment mark region II may be exposed. For example, the upper surface of the substrate 100 in the alignment mark region II may be coplanar with as the upper surface of the substrate 100 in the logic cell region I.

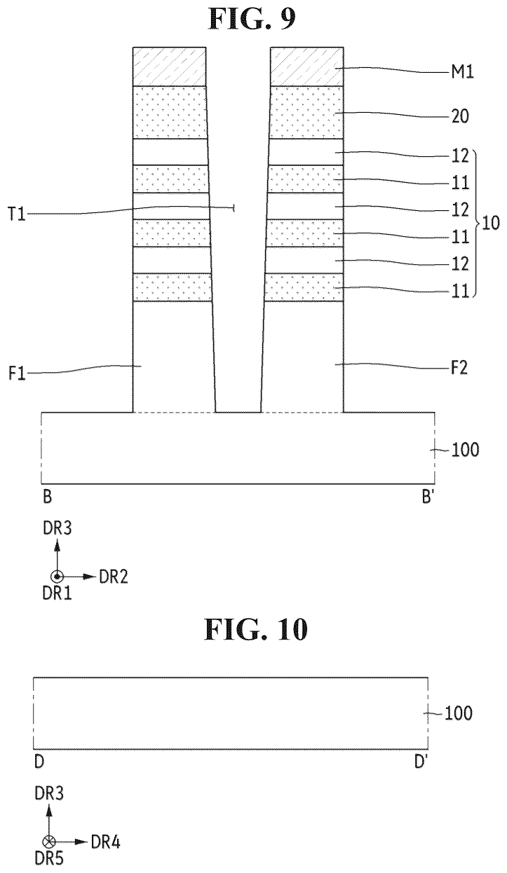

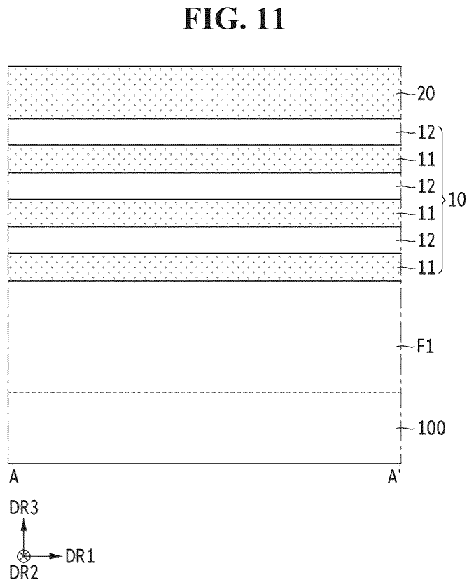

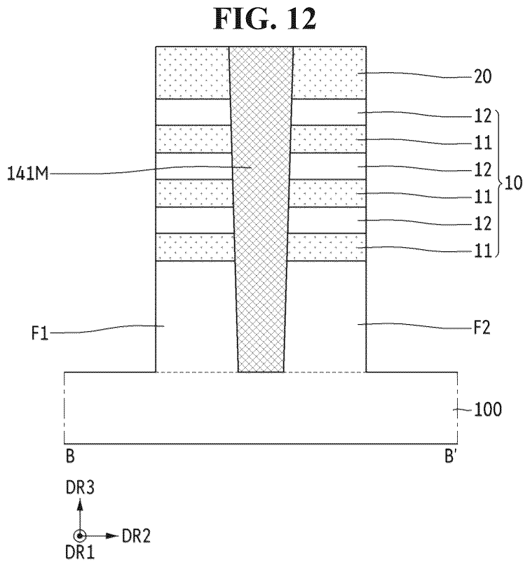

Referring to FIGS. 11 and 12, an isolation material layer 141M may be formed inside the first isolation trench T1. For example, the upper surface of the isolation material layer 141M may be coplanar with as the upper surface of the third semiconductor layer 20. For example, while the isolation material layer 141M is being formed, the first mask pattern M1 (see FIGS. 8 and 9) may be etched. The isolation material layer 141M may include the same material as the first portion 141 of the channel isolation layer 140 shown in FIGS. 4 and 5.

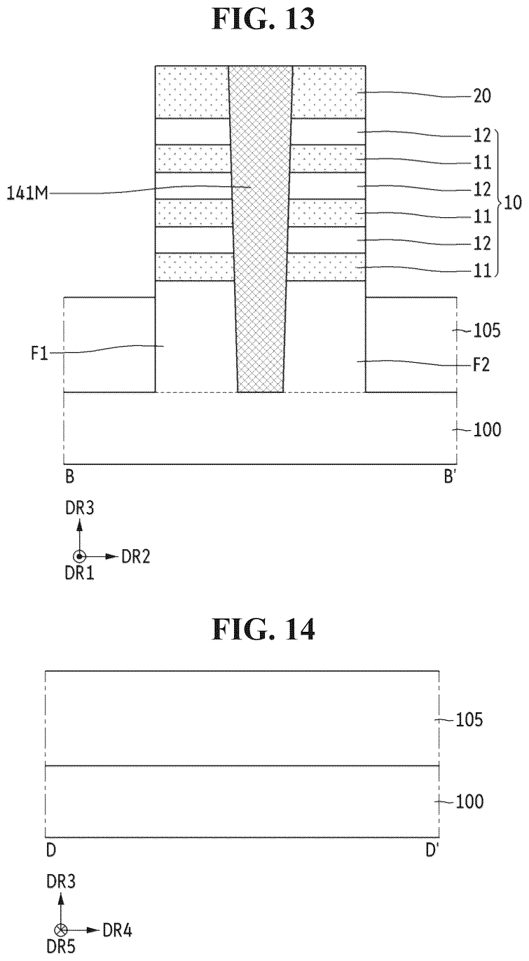

Referring to FIGS. 13 and 14, the field insulating layer 105 may be formed on the upper surface of the substrate 100. For example, the field insulating layer 105 may be formed to surround the sidewalls of each of the first and second active patterns F1, F2 on the upper surface of the substrate 100 in the logic cell region I. Additionally, the field insulating layer 105 may be formed to cover the upper surface of the substrate 100 in the alignment mark region II.

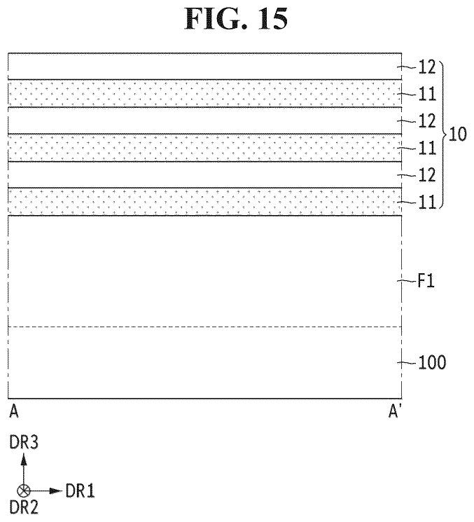

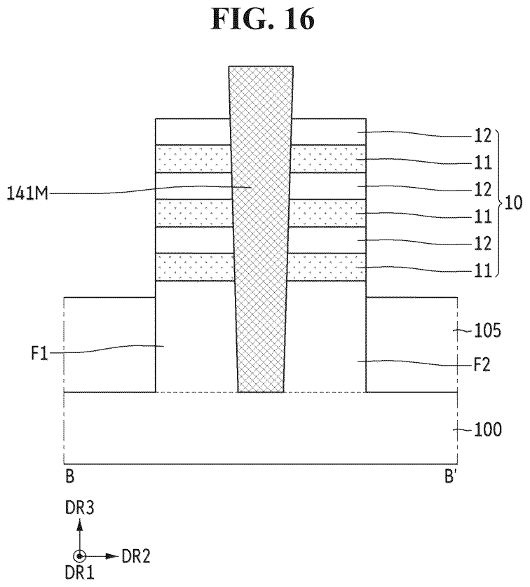

Referring to FIGS. 15 and 16, the third semiconductor layer 20 (see FIG. 13) may be etched. Through this etching process, a portion of both sidewalls of the isolation material layer 141M in the second horizontal direction DR2 may be exposed.

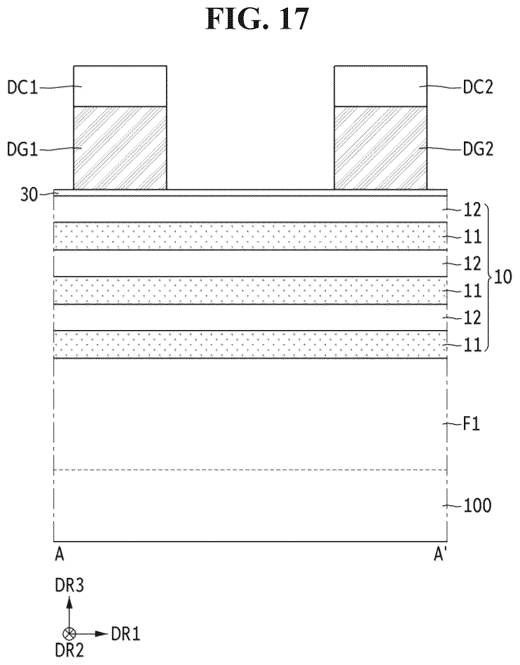

Referring to FIGS. 17 to 20, a pad oxide layer 30 may be formed to cover the upper surface of the field insulating layer 105, the exposed sidewalls of each of the first and second active patterns F1, F2, the sidewalls and upper surface of the stacked structure 10, and the exposed sidewalls and upper surface of the isolation material layer 141M. For example, the pad oxide layer 30 may be formed conformally. The pad oxide layer 30 may include, for example, silicon oxide (SiO₂).

Subsequently, on the upper surface of the substrate 100 in the logic cell region I, first and second dummy gates DG1, DG2 and first and second dummy capping patterns DC1, DC2 extending in the second horizontal direction DR2 on the pad oxide layer 30 may be formed. The first dummy capping pattern DC1 may be formed on the first dummy gate DG1. Further, the second dummy capping pattern DC2 may be formed on the second dummy gate DG2. Each of the second dummy gate DG2 and the second dummy capping pattern DC2 may be spaced apart from each of the first dummy gate DG1 and the first dummy capping pattern DC1 in the first horizontal direction DR1.

Additionally, on the upper surface of the substrate 100 in the alignment mark region II, first and second alignment dummy gates ADG1, ADG2 and first and second alignment dummy capping patterns ADC1, ADC2 extending in the fourth horizontal direction DR5 on the pad oxide layer 30 may be formed. The first alignment dummy capping pattern ADC1 may be formed on the first alignment dummy gate ADG1. Further, the second alignment dummy capping pattern ADC2 may be formed on the second alignment dummy gate ADG2. Each of the second alignment dummy gate ADG2 and the second alignment dummy capping pattern ADC2 may be spaced apart from each of the first alignment dummy gate ADG1 and the first alignment dummy capping pattern ADC1 in the third horizontal direction DR4. For example, each of the first and second dummy gates DG1, DG2, and each of the first and second alignment dummy gates ADG1, ADG2 may include polysilicon.

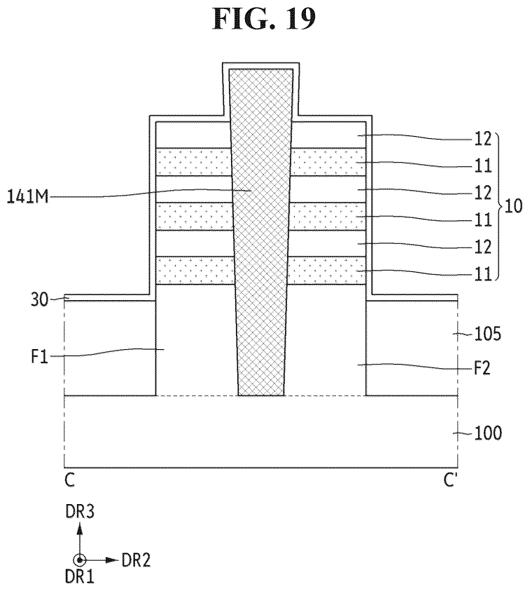

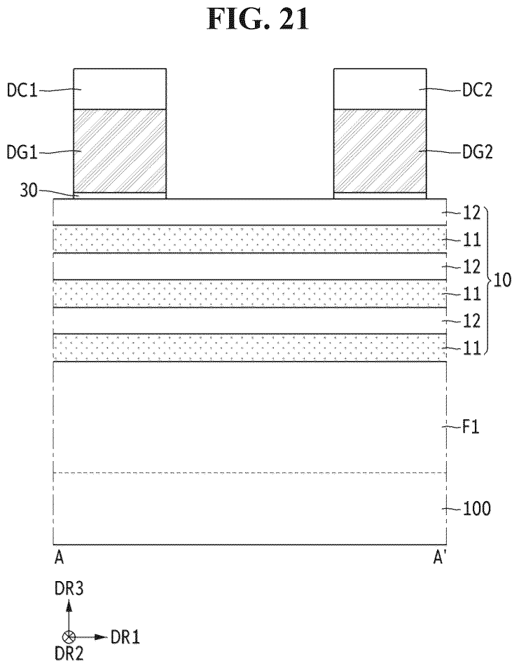

Referring to FIGS. 21 to 23, on the upper surface of the substrate 100 in the logic cell region I, the remaining portion of the pad oxide layer 30 may be etched except for the portion that overlaps with each of the first and second dummy gates DG1, DG2 in the vertical direction DR3. While the pad oxide layer 30 is being etched, a portion of the isolation material layer 141M (see FIG. 19) of the portion where each of the first and second dummy gates DG1, DG2 is not formed may be etched. After this etching process is completed, the remaining isolation material layer 141M (see FIG. 19) may be defined as the first portion 141 of the channel isolation layer 140 (see FIGS. 4 and 5). For example, in the portion each of the first and second dummy gates DG1, DG2 is not formed, the upper surface of the first portion 141 of the channel isolation layer 140 (see FIGS. 4 and 5) may be formed lower than the upper surface of the stacked structure 10.

Additionally, on the upper surface of the substrate 100 in the alignment mark region II, the remaining portion of the pad oxide layer 30, except for the portion that overlaps with each of the first and second alignment dummy gates ADG1, ADG2 in the vertical direction DR3, may be etched.

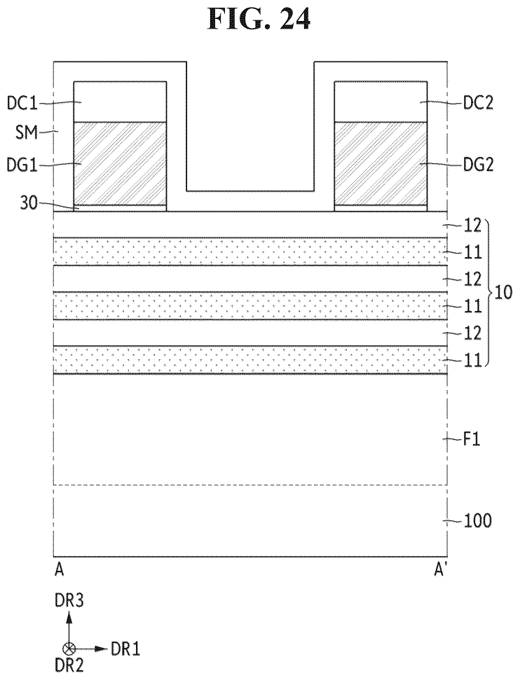

Referring to FIGS. 24 to 26, the spacer material layer SM may be formed to cover the exposed surfaces of each of the first and second dummy gates DG1, DG2, the first and second dummy capping patterns DC1, DC2, the stacked structure 10, the field insulating layer 105, and the first portion 141 of the channel isolation layer 140 (see FIGS. 4 and 5), the first and second alignment dummy gates ADG1, ADG2, and the first and second alignment dummy capping patterns ADC1, ADC2. For example, the spacer material layer SM may be formed conformally. For example, the spacer material layer SM may include the same material as the first and second gate spacers 111, 112 (see FIG. 3), the first and second source/drain spacers 111S, 112S (see FIG. 5), and the first and second alignment spacers 111A, 112A.

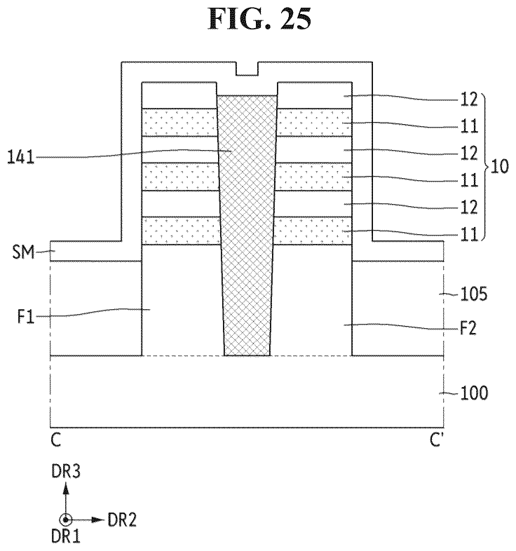

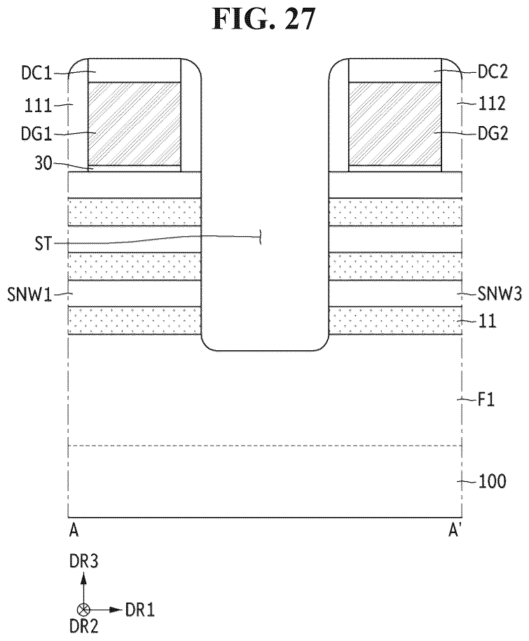

Referring to FIGS. 27 to 29, on the upper surface of the substrate 100 in the logic cell region I, the stacked structure 10 (see FIGS. 24 and 25) may be etched to form the source/drain trench ST using the first and second dummy capping patterns DC1, DC2 and the first and second dummy gates DG1, DG2 as masks. For example, after the source/drain trench ST is formed, the spacer material layer SM (see FIG. 24) remaining on both sidewalls of the first dummy gate DG1 may be defined as the first gate spacer 111, and the spacer material layer SM (see FIG. 24) remaining on both sidewalls of the second dummy gate DG2 may be defined as the second gate spacer 112.

For example, while the source/drain trench ST is being formed, in the portion where the first and second dummy gates DG1, DG2 are not being formed, a portion of the spacer material layer SM (see FIGS. 24 to 26) may remain unetched on both sidewalls in the second horizontal direction DR2 of the first portion 141 of the channel isolation layer 140 (see FIGS. 4 and 5). For example, in a portion where the first and second dummy gates DG1, DG2 are not formed, the spacer material layer SM (see FIGS. 24 to 26) that remains unetched on both sidewalls in the second horizontal direction DR2 of the first portion 141 of the channel isolation layer 140 (see FIGS. 4 and 5) may be defined as the first and second source/drain spacers 111S, 112S.

For example, after the source/drain trench ST is formed, the second semiconductor layer 12 (see FIG. 24) remaining beneath the first dummy gate DG1 may be defined as the plurality of first sub-nanosheets SNW1, and the second semiconductor layer 12 (see FIG. 24) remaining beneath the second dummy gate DG2 may be defined as the plurality of third sub-nanosheets SNW3.

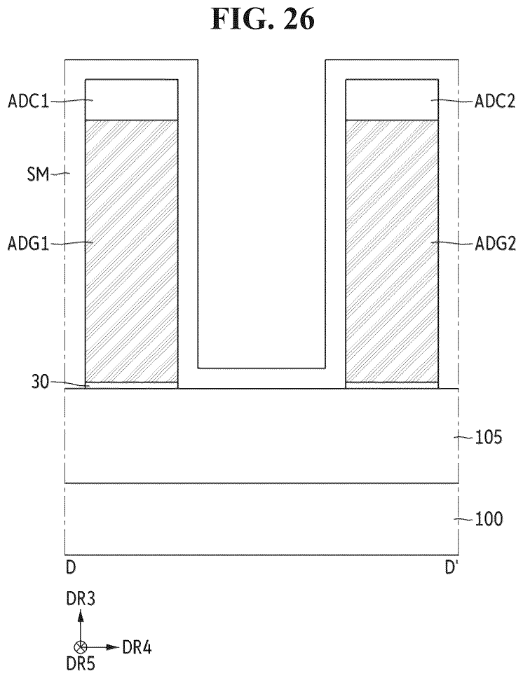

Additionally, on the upper surface of the substrate 100 in the alignment mark region II, the spacer material layer SM (see FIG. 26) formed on the upper surface of the field insulating layer 105 may be etched using the first and second alignment dummy capping patterns ADC1, ADC2 and the first and second alignment dummy gates ADG1, ADG2 as masks. For example, after this etching process is completed, the spacer material layer SM (see FIG. 26) remaining on both sidewalls of the first alignment dummy gate ADG1 may be defined as the first alignment spacer 111A, and the spacer material layer SM (see FIG. 26) remaining on both sidewalls of the second alignment dummy gate ADG2 may be defined as the second alignment spacer 112A.

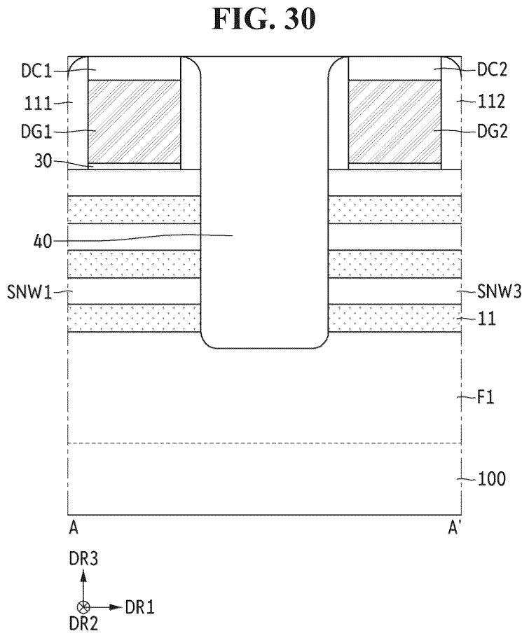

Referring to FIGS. 30 to 32, a sacrificial layer 40 may be formed on the upper surface of the substrate 100 in each of the logic cell region I and the alignment mark region II. For example, the upper surface of the sacrificial layer 40 may be coplanar with as the upper surface of each of the first and second dummy capping patterns DC1, DC2, and the first and second alignment dummy capping patterns ADC1, ADC2. For example, the sacrificial layer 40 may include SOH (Spin-On Hardmask).

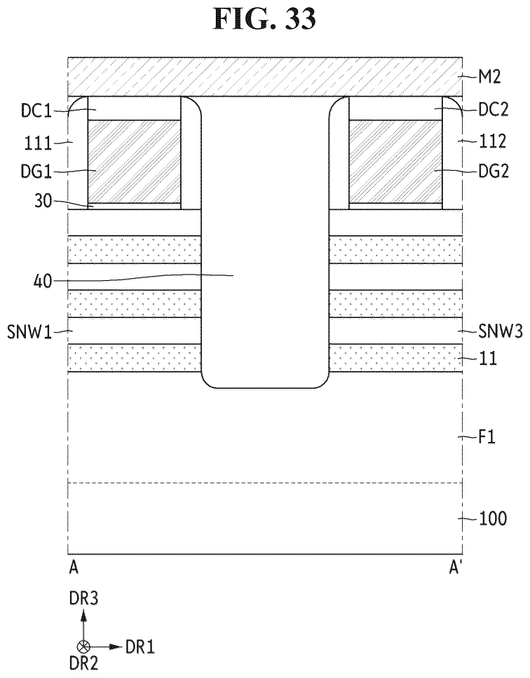

Referring to FIG. 33 to 35, a second mask pattern M2 may be formed on the upper surface of the substrate 100 in each of the logic cell region I and the alignment mark region II. Then, using the second mask pattern M2 as a mask, the sacrificial layer 40 may be etched. Through this etching process, a second isolation trench T2 may be formed on the upper surface of the first portion 141 of the channel isolation layer 140 (see FIGS. 4 and 5). Through the second isolation trench T2, the upper surface of the first portion 141 of the channel isolation layer 140 (see FIGS. 4 and 5) may be exposed. Further, through this etching process, the alignment trench AT may be formed between the first alignment spacer 111A and the second alignment spacer 112A. Through the alignment trench AT, the field insulating layer 105, the first and second alignment spacers 111A, 112A may be exposed.

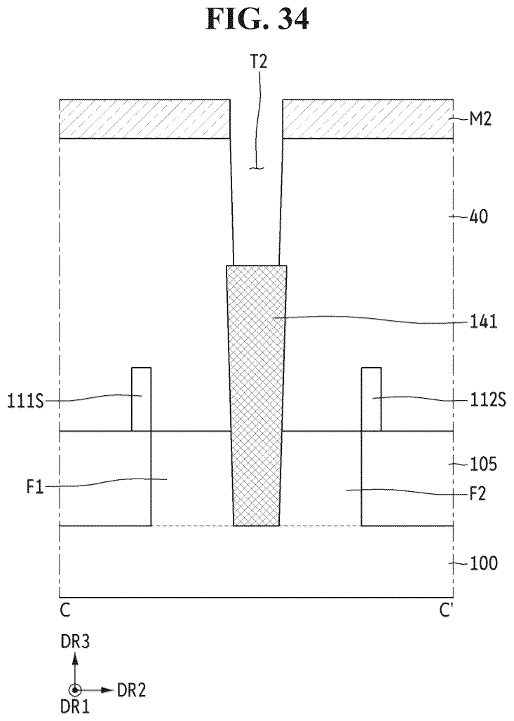

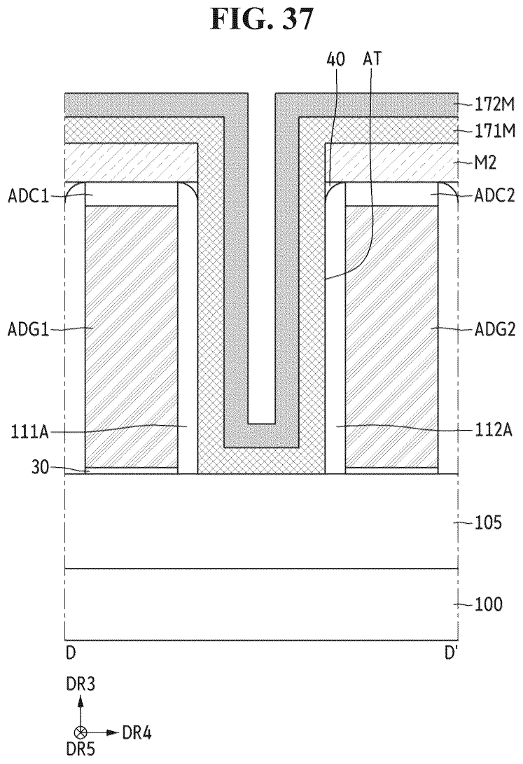

Referring to FIGS. 36 and 37, on the upper surface of the substrate 100 in the logic cell region I, the first insulating material layer 171M may be formed to fill the inside of the second isolation trench T2 (see FIG. 34). Additionally, on the upper surface of the substrate 100 in the alignment mark region II, the first insulating material layer 171M may be formed along the sidewalls and the bottom surface of the alignment trench AT. For example, the first insulating material layer 171M may be formed on the upper surface of the second mask pattern M2. For example, the first insulating material layer 171M may be formed conformally. The first insulating material layer 171M includes the same material as each of the second portion of the channel isolation layer 140 (see FIG. 5) and the first layer 171 (see FIG. 7) of the alignment insulating structure 170 (see FIG. 7).

Subsequently, the second insulating material layer 172M may be formed on the first insulating material layer 171M. For example, on the upper surface of the substrate 100 in the alignment mark region II, the second insulating material layer 172M may fill a portion of the alignment trench AT. For example, the second insulating material layer 172M may be formed conformally. The second insulating material layer 172M may include the same material as the second layer 172 (see FIG. 7) of the alignment insulating structure 170 (see FIG. 7).

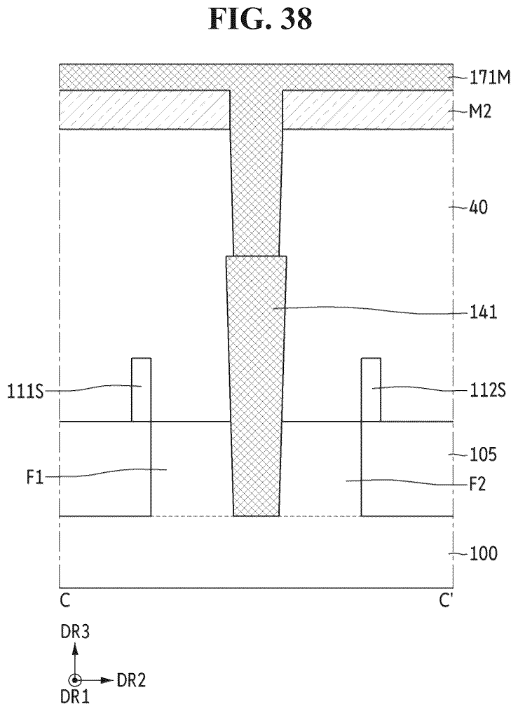

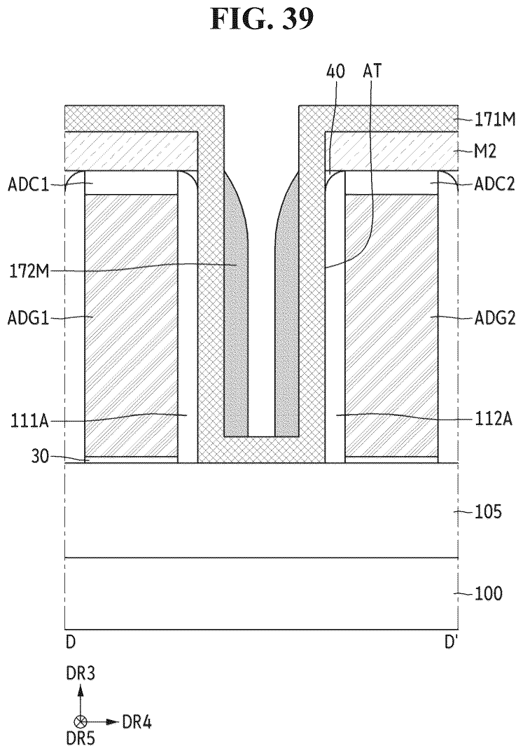

Referring to FIGS. 38 and 39, a portion of the second insulating material layer 172M may be etched by performing an etch back etching process. Through this etching process, the remaining second insulating material layer 172M, except for the portion of the second insulating material layer 172M formed inside the alignment trench AT, may be etched away. The upper sidewalls of the remaining second insulating material layer 172M may have a sloped profile. Additionally, a portion of the first insulating material layer 171M may be exposed between the second insulating material layers 172M.

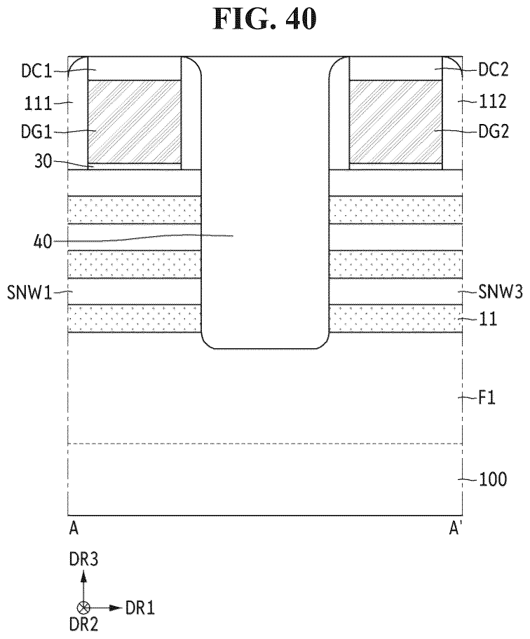

Referring to FIGS. 40 to 42, on the upper surface of the substrate 100 in each of the logic cell region I and the alignment mark region II, a third insulating material layer 173M may be formed on the first insulating material layer 171M and the second insulating material layer 172M. For example, on the upper surface of the substrate 100 in the alignment mark region II, the third insulating material layer 173M may fill the inside of the alignment trench AT on the second insulating material layer 172M. Subsequently, a planarization process may be performed to expose the upper surface of each of the first and second capping patterns 131, 132, and the first and second alignment capping patterns 131A, 132A.

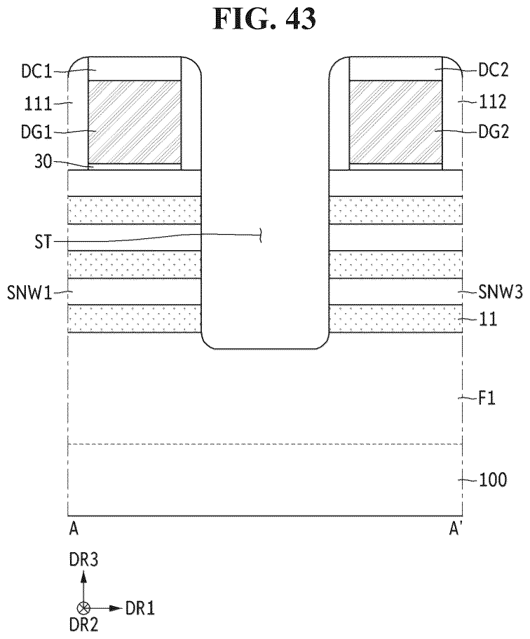

Referring to FIGS. 43 to 45, the sacrificial layer 40 (see FIGS. 40 to 42) may be etched.

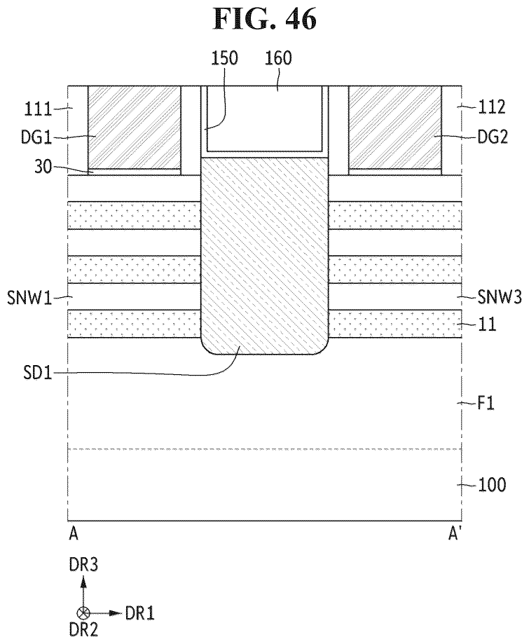

Referring to FIG. 46 to 48, on the upper surface of the substrate 100 in the logic cell region I, the first source/drain region SD1 may be formed inside the source/drain trench ST (see FIG. 43). Subsequently, after the etching stop layer 150 and the interlayer insulating layer 160 are formed sequentially, a planarization process may be performed to expose the upper surface of each of the first and second dummy gates DG1, DG2, and the first and second alignment dummy gates ADG1, ADG2.

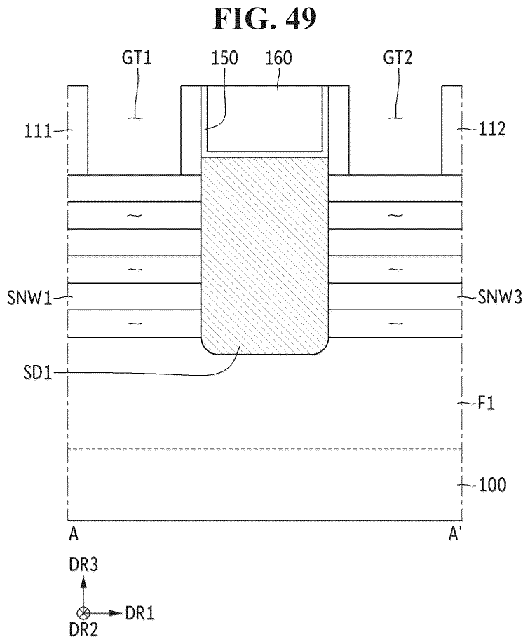

Referring to FIGS. 49 to 51, on the upper surface of the substrate 100 in the logic cell region I, the first and second dummy gates DG1, DG2 (see FIG. 46), the pad oxide layer 30 (see FIG. 46), and the first semiconductor layer 11 (see FIG. 46) may be etched. For example, the portion where the first dummy gate DG1 (see FIG. 46), the pad oxide layer 30 (see FIG. 46), and the first semiconductor layer 11 (see FIG. 46) are etched may be defined as the first gate trench GT1. Additionally, the portion where the second dummy gate DG2 (see FIG. 46), the pad oxide layer 30 (see FIG. 46), and the first semiconductor layer 11 (see FIG. 46) are etched may be defined as the second gate trench GT2.

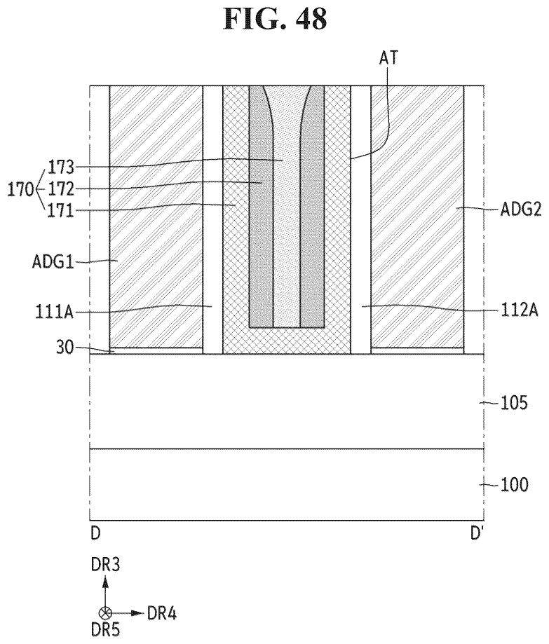

Further, on the upper surface of the substrate 100 in the alignment mark region II, the first and second alignment dummy gates ADG1, ADG2 (see FIG. 48) and the pad oxide layer 30 (see FIG. 48) may be etched. For example, the portion in which the first alignment dummy gate ADG1 (see FIG. 48) and the pad oxide layer 30 (see FIG. 48) are etched may be defined as the first alignment structure trench AST1. Additionally, the portion in which the second alignment dummy gate ADG2 (see FIG. 48) and the pad oxide layer 30 (see FIG. 48) are etched may be defined as the second alignment structure trench AST2.

Referring to FIGS. 1 to 7, on the upper surface of the substrate 100 in the logic cell region I, the first gate insulating layer 121, the first gate electrode G1, and the first capping pattern 131 may be formed sequentially inside the first gate trench GT1 (see FIG. 49). Further, the second gate insulating layer 122, the second gate electrode G2, and the second capping pattern 132 may be formed sequentially inside the second gate trench GT2 (see FIG. 49).

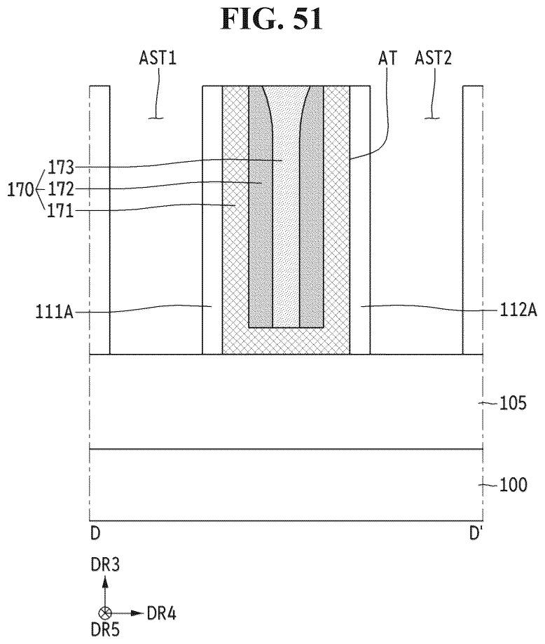

Additionally, on the upper surface of the substrate 100 in the alignment mark region II, the first alignment gate insulating layer 121A, the first alignment gate electrode AG1, and the first alignment capping pattern 131A may be formed sequentially inside the first alignment structure trench AST1 (see FIG. 51). Moreover, the second alignment gate insulating layer 122A, the second alignment gate electrode AG2, and the second alignment capping pattern 132A may be formed sequentially inside the second alignment structure trench AST2 (see FIG. 51). Through this fabrication process, the semiconductor device shown in FIGS. 1 to 7 may be fabricated.

The fabrication method of the semiconductor device according to one or more embodiments may form the alignment insulating structure 170 which is formed between the first alignment structure AS1 and the second alignment structure AS2 in the alignment mark region II as multiple layers including the first to third layers 171, 172, 173. This may effectively fill the region where the alignment insulating structure 170 is formed. That is, it may prevent voids from forming in the region where the alignment insulating structure 170 is formed, and prevent each of the first and second alignment structures AS1, AS2 from tilting during the fabrication process. Additionally, the fabrication method of the semiconductor device according to one or more embodiments may simplify the fabrication process by forming a portion of the channel isolation layer 140 in the logic cell region I through the process in which the first layer 171 of the insulating structure 170 is formed.

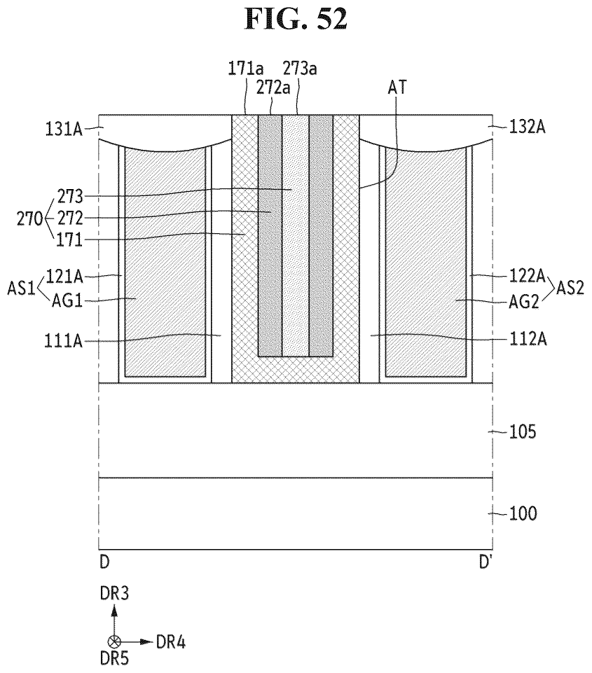

Hereinafter, the semiconductor device according to one or more embodiments will be described with reference to FIG. 52. The description will focus on the differences from the semiconductor device shown in FIGS. 1 to 7. Thus, description of aspects that are the same as or similar to those described above may be omitted.

FIG. 52 is a cross-sectional view illustrating a semiconductor device according to one or more embodiments.

Referring to FIG. 52, in the semiconductor device according to one or more embodiments, the second layer 272 of the alignment insulating structure 270 may be formed conformally.

For example, the alignment insulating structure 270 may include the first layer 171, the second layer 272, and the third layer 273. For example, the width of the upper surface 272a of the second layer 272 of the alignment insulating structure 270 in the third horizontal direction DR4 may be the same as the width of the bottom surface of the second layer 272 of the alignment insulating structure 270 in the third horizontal direction DR4. For example, the width of the upper surface 273a of the third layer 273 of the alignment insulating structure 270 in the third horizontal direction DR4 may be the same as the width of the bottom surface of the third layer 273 of the alignment insulating structure 270 in the third horizontal direction DR4.

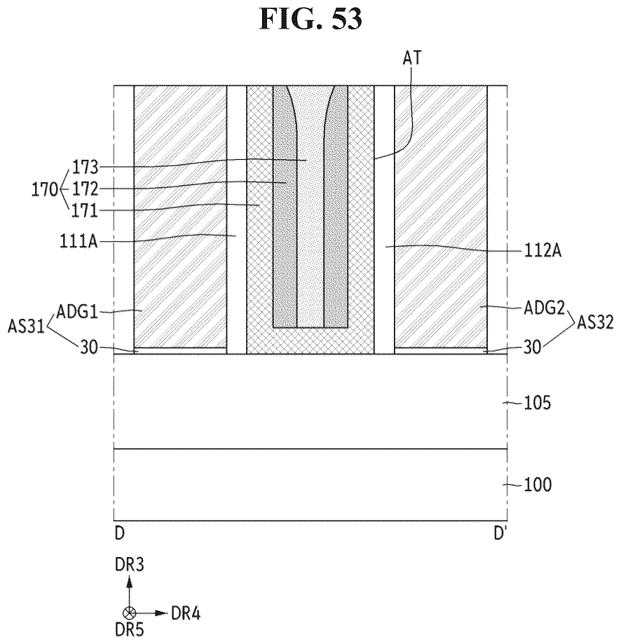

Hereinafter, the semiconductor device according to one or more embodiments will be described with reference to FIG. 53. The description will focus on the differences from the semiconductor device shown in FIGS. 1 to 7. Thus, description of aspects that are the same as or similar to those described above may be omitted.

FIG. 53 is a cross-sectional view illustrating a semiconductor device according to one or more embodiments.

Referring to FIG. 53, in the semiconductor device according to one or more embodiments, each of the first alignment structure AS31 and the second alignment structure AS32 may include polysilicon.

For example, the first alignment structure AS31 may include the pad oxide layer 30 and the first alignment dummy gate ADG1. The second alignment structure AS32 may include the pad oxide layer 30 and the second alignment dummy gate ADG2. For example, each of the first and second alignment dummy gates ADG1, ADG2 may include polysilicon. For example, the upper surface of each of the first and second alignment dummy gates ADG1, ADG2 may be coplanar with as the uppermost surface 171a of the first layer 171.

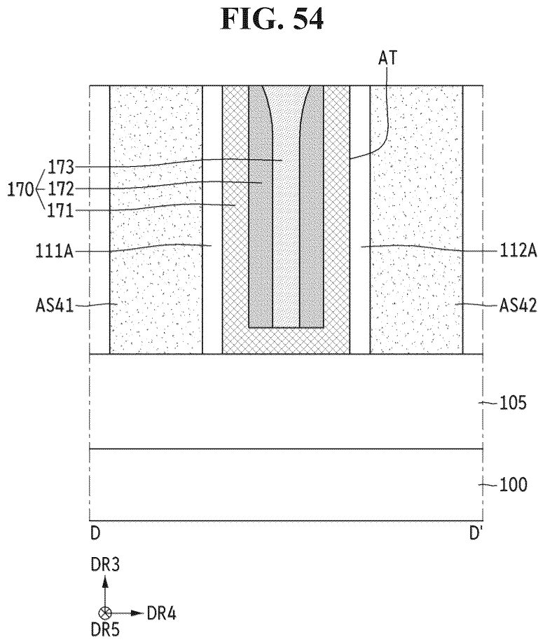

Hereinafter, the semiconductor device according to one or more embodiments will be described with reference to FIG. 54. The description will focus on the differences from the semiconductor device shown in FIGS. 1 to 7. Thus, description of aspects that are the same as or similar to those described above may be omitted.

FIG. 54 is a cross-sectional view illustrating a semiconductor device according to one or more embodiments.

Referring to FIG. 54, in the semiconductor device according to another example embodiments, each of the first alignment structure AS41 and the second alignment structure AS41 may be formed as a single layer.

For example, each of the first and second alignment structures AS41, AS42 may include an insulating material. For example, each of the first and second alignment structures AS41, AS42 may include at least one of silicon oxide, silicon nitride, silicon oxynitride, and a low-k dielectric material. For example, the upper surface of each of the first and second alignment structures AS41, AS42 may be coplanar with as the uppermost surface 171a of the first layer 171.

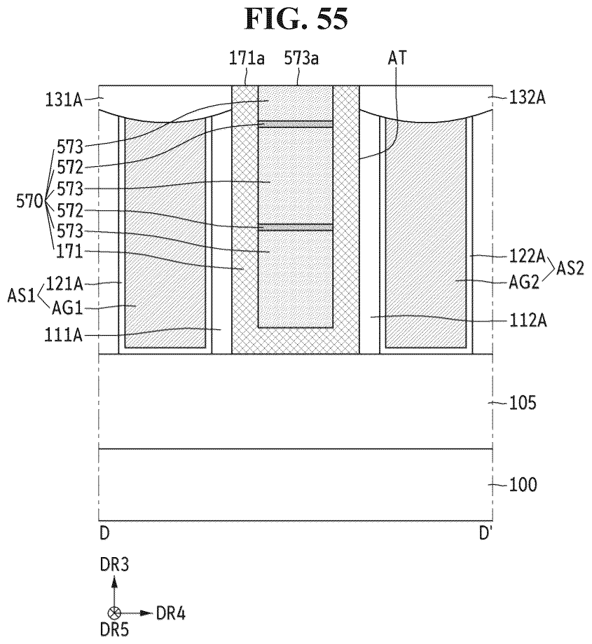

Hereinafter, the semiconductor device according to one or more embodiments will be described with reference to FIG. 55. The description will focus on the differences from the semiconductor device shown in FIGS. 1 to 7. Thus, description of aspects that are the same as or similar to those described above may be omitted.

FIG. 55 is a cross-sectional view illustrating a semiconductor device according to one or more embodiments.

Referring to FIG. 55, in the semiconductor device according to one or more embodiments of the present invention, the alignment insulating structure 570 may include a second layer 572 and a third layer 573 alternately stacked in the vertical direction DR3.

For example, the alignment insulating structure 570 may include the first layer 171, the second layer 572, and the third layer 573. The first layer 171 of the alignment insulating structure 570 may be disposed along the sidewalls and bottom surface of the alignment trench AT. The third layer 573 of the alignment insulating structure 570 and the second layer 572 of the alignment insulating structure 570 may be alternately stacked in the vertical direction DR3 on the first layer 171 of the alignment insulating structure 570. For example, the bottom surface of the lowermost third layer 573 of the alignment insulating structure 570 may contact the first layer 171 of the alignment insulating structure 570. For example, the upper surface 573a of the uppermost third layer 573 of the alignment insulating structure 570 may be coplanar with as the uppermost surface 171a of the first layer 171 of the alignment insulating structure 570.

For example, both sidewalls that are across the third horizontal direction DR4 of each of the second layer 572 of the alignment insulating structure 570 and the third layer 573 of the alignment insulating structure 570 may contact the first layer 171 of the alignment insulating structure 570. For example, the thickness in the vertical direction DR3 of the second layer 572 of the alignment insulating structure 570 may range from 1 nm to 5 nm. For example, the second layer 572 of the alignment insulating structure 570 may include the same material as the second layer 172 shown in FIG. 7. For example, the second layer 572 of the alignment insulating structure 570 may be formed through a thermal process or a plasma process. For example, the third layer 573 of the alignment insulating structure 570 may include the same material as the third layer 173 shown in FIG. 7.

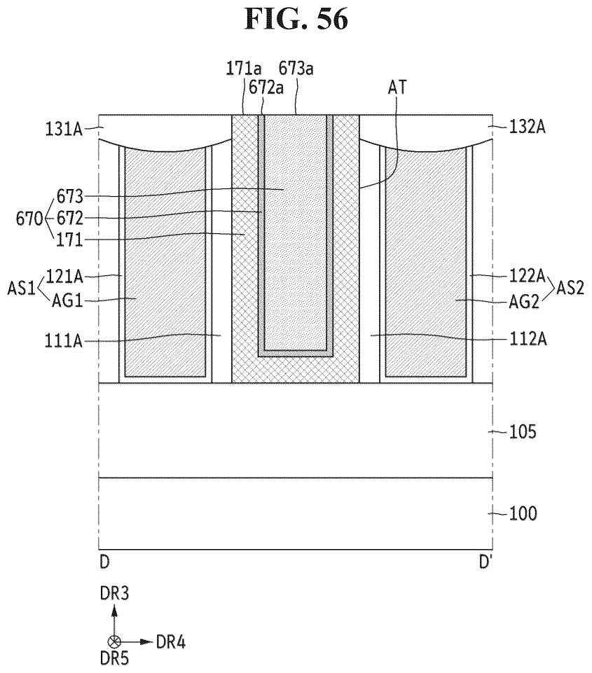

Hereinafter, the semiconductor device according to one or more embodiments will be described with reference to FIG. 56. The description will focus on the differences from the semiconductor device shown in FIGS. 1 to 7. Thus, description of aspects that are the same as or similar to those described above may be omitted

FIG. 56 is a cross-sectional view illustrating a semiconductor device according to one or more embodiments.

Referring to FIG. 56, the semiconductor device according to one or more embodiments may have the second layer 672 of the alignment insulating structure 670 disposed along the interface between the first layer 171 of the alignment insulating structure 670 and the third layer 673 of the alignment insulating structure 670.

For example, each of the second layer 672 of the alignment insulating structure 670 and the third layer 673 of the alignment insulating structure 670 may be conformally formed. For example, the uppermost surface 171a of the first layer 171 of the alignment insulating structure 670, the uppermost surface 672a of the second layer 672 of the alignment insulating structure 670, and the upper surface 673a of the third layer 673 of the alignment insulating structure 670 may be coplanar with. For example, the third layer 673 of the alignment insulating structure 670 may be spaced apart from the first layer 171 of the alignment insulating structure 670. For example, the thickness of the second layer 672 of the alignment insulating structure 670 may range from 1 nm to 5 nm. For example, the second layer 672 of the alignment insulating structure 670 may include silicon oxide (SiO₂). For example, the third layer 673 of the alignment insulating structure 670 may include at least one of silicon oxide, silicon nitride, silicon oxynitride, and a low-k dielectric material.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a substrate comprising a logic cell region and an alignment mark region;
a first active pattern on the substrate and in the logic cell region, the first active pattern extending in a first horizontal direction;
a second active pattern on the substrate and in the logic cell region, the second active pattern extending in the first horizontal direction and spaced apart from the first active pattern in a second horizontal direction that is different from the first horizontal direction;
a channel isolation layer on the substrate and in the logic cell region, the channel isolation layer extending in the first horizontal direction and isolating the first active pattern from the second active pattern in the second horizontal direction, wherein sidewalls of the channel isolation layer that are across the second horizontal direction contact the first active pattern and the second active pattern;
a first alignment structure on the substrate and in the alignment mark region, the first alignment structure extending in a third horizontal direction;
a second alignment structure on the substrate and in the alignment mark region, the second alignment structure extending in the third horizontal direction and spaced apart from the first alignment structure in a fourth horizontal direction that is different from the third horizontal direction;
a first alignment spacer contacting sidewalls of the first alignment structure that are across the fourth horizontal direction;
a second alignment spacer contacting sidewalls of the second alignment structure that are across the fourth horizontal direction;
an alignment trench between the first alignment spacer and the second alignment spacer; and
an alignment insulating structure in the alignment trench,
wherein the alignment insulating structure comprises,
a first layer along sidewalls and a bottom surface of the alignment trench, the first layer contacting the first alignment spacer and the second alignment spacer, wherein a material of the first layer is the same as a material of the channel isolation layer, and an upper surface of the first layer is coplanar with an upper surface of the channel isolation layer;
a second layer on the first layer and in the alignment trench, wherein a material of second layer is different from the material of the first layer; and
a third layer filling a remaining portion of the alignment trench, wherein a material of the third layer is different from the material of the second layer.

2. The semiconductor device of claim 1, further comprising:
a plurality of first sub-nanosheets on the first active pattern and spaced apart from each other in a vertical direction, wherein sidewalls of the plurality of first sub-nanosheets that are across the second horizontal direction contact the channel isolation layer; and
a plurality of second sub-nanosheets on the second active pattern and spaced apart from each other in the vertical direction, wherein the plurality of second sub-nanosheets are spaced apart from the plurality of first sub-nanosheets in the second horizontal direction, and wherein sidewalls of the plurality of second sub-nanosheets that are across the second horizontal direction contact the channel isolation layer.

3. The semiconductor device of claim 2, further comprising:
a gate electrode on the first active pattern and the second active pattern, the gate electrode extending in the second horizontal direction and surrounding each of the plurality of first sub-nanosheets and the plurality of second sub-nanosheets; and
a first capping pattern contacting an upper surface of the gate electrode, the first capping pattern extending in the second horizontal direction, wherein an upper surface of the first capping pattern is coplanar with the upper surface of the first layer.

4. The semiconductor device of claim 1, further comprising:
a first source/drain region on the first active pattern, the first source/drain region contacting a first sidewall of the channel isolation layer that is across the second horizontal direction; and
a second source/drain region on the second active pattern, the second source/drain region contacting a second sidewall of the channel isolation layer opposite the first sidewall of the channel isolation layer in the second horizontal direction.

5. The semiconductor device of claim 1, wherein the third horizontal direction is the same as the second horizontal direction, and the fourth horizontal direction is the same as the first horizontal direction.

6. The semiconductor device of claim 1, wherein the upper surface of the first layer is coplanar with an upper surface of the third layer.

7. The semiconductor device of claim 1, wherein the second layer extends in a vertical direction along inner sidewalls of the first layer, and
wherein a bottom surface of the third layer contacts the first layer.

8. The semiconductor device of claim 1, wherein the third layer and the second layer are alternately stacked in a vertical direction, and
wherein sidewalls of the third layer and the second layer that are across the fourth horizontal direction contact the first layer.

9. The semiconductor device of claim 1, wherein a width of an upper surface of the third layer in the fourth horizontal direction is greater than a width of a bottom surface of the third layer in the fourth horizontal direction.

10. The semiconductor device of claim 1, further comprising:
a first alignment capping pattern contacting an upper surface of the first alignment structure, the first alignment capping pattern extending in the third horizontal direction; and
a second alignment capping pattern contacting an upper surface of the second alignment structure, the second alignment capping pattern extending in the third horizontal direction, wherein the second alignment capping pattern is spaced apart from the first alignment capping pattern in the fourth horizontal direction,
wherein an upper surface of first alignment capping pattern and an upper surface of the second alignment capping pattern is coplanar with the upper surface of the first layer.

11. The semiconductor device of claim 1, wherein the first alignment structure comprises a first alignment dummy gate comprising polysilicon,
wherein the second alignment structure comprises a second alignment dummy gate comprising polysilicon, and
wherein an upper surface of the first alignment dummy gate and an upper surface of the second alignment dummy gate is coplanar with the upper surface of the first layer.

12. The semiconductor device of claim 1, wherein the first alignment structure comprises a single layer,
wherein the second alignment structure comprises a single layer,
wherein the first alignment structure and the second alignment structure comprise an insulating material, and
wherein an upper surface of the first and alignment structure and an upper surface of the second alignment structure are coplanar with the upper surface of the first layer.

13. A semiconductor device comprising:
a substrate comprising a logic cell region and an alignment mark region;
a channel isolation layer on the substrate and in the logic cell region, the channel isolation layer extending in a first horizontal direction;
a plurality of first sub-nanosheets on the substrate and in the logic cell region, the plurality of first sub-nanosheets being spaced apart from each other in a vertical direction, wherein sidewalls of the plurality of first sub-nanosheets that are across a second horizontal direction different from the first horizontal direction contact the channel isolation layer;
a plurality of second sub-nanosheets on the substrate and in the logic cell region, the plurality of second sub-nanosheets spaced apart from each other in the vertical direction, and spaced apart from the plurality of first sub-nanosheets in the second horizontal direction, wherein sidewalls of the plurality of second sub-nanosheets that are across the second horizontal direction contact the channel isolation layer;
a gate electrode on the substrate and in the logic cell region, the gate electrode extending in the second horizontal direction and surrounding the plurality of first sub-nanosheets and the plurality of second sub-nanosheets;
a first alignment gate electrode on the substrate and in the alignment mark region, the first alignment gate electrode extending in a third horizontal direction;
a second alignment gate electrode on the substrate and in the alignment mark region, the second alignment gate electrode extending in the third horizontal direction and spaced apart from the first alignment gate electrode in a fourth horizontal direction that is different from the third horizontal direction;
a first alignment spacer on sidewalls of the first alignment gate electrode that are across the fourth horizontal direction;
a second alignment spacer on sidewalls of the second alignment gate electrode that are across the fourth horizontal direction;
an alignment trench between the first alignment spacer and the second alignment spacer; and
an alignment insulating structure in the alignment trench,
wherein the alignment insulating structure comprises,
a first layer along sidewalls and a bottom surface of the alignment trench, the first layer contacting each of the first alignment spacer and the second alignment spacer, wherein a material of the first layer the same as a material of the channel isolation layer, and an upper surface of the first layer is coplanar with an upper surface of the channel isolation layer;
a second layer on the first layer and in the alignment trench, wherein a material of second layer is different from the material of the first layer; and
a third layer filling a remaining portion of the alignment trench, wherein a material of the third layer is different from the material of the second layer.

14. The semiconductor device of claim 13, further comprising:
a first alignment capping pattern contacting an upper surface of the first alignment gate electrode, the first alignment capping pattern extending in the third horizontal direction; and
a second alignment capping pattern contacting an upper surface of the second alignment gate electrode, the second alignment capping pattern extending in the third horizontal direction, wherein the second alignment capping pattern is spaced apart from the first alignment capping pattern in the fourth horizontal direction,
wherein an upper surface of the first alignment capping pattern and an upper surface of the second alignment capping pattern are coplanar with the upper surface of the first layer.

15. The semiconductor device of claim 13, further comprising:
a first capping pattern contacting an upper surface of the gate electrode, the first capping pattern extending in the second horizontal direction,
wherein an upper surface of the first capping pattern is coplanar with the upper surface of the first layer.

16. The semiconductor device of claim 15, wherein a bottom surface of the first capping pattern contacts the channel isolation layer.

17. The semiconductor device of claim 13, wherein the third horizontal direction is the same as the first horizontal direction, and the fourth horizontal direction is the same as the second horizontal direction.

18. The semiconductor device of claim 13, wherein the third layer and the second layer are alternately stacked in the vertical direction, and
wherein sidewalls of the third layer and the second layer that are across the fourth horizontal direction contact the first layer.

19. The semiconductor device of claim 13, wherein the second layer is along an interface between the first layer and the third layer, and
wherein the third layer is spaced apart from the first layer.

20. A semiconductor device comprising:
a substrate comprising a logic cell region and an alignment mark region;
a first active pattern on the substrate and in the logic cell region, the first active pattern extending in a first horizontal direction;
a second active pattern on the substrate and in the logic cell region, the second active pattern extending in the first horizontal direction and spaced apart from the first active pattern in a second horizontal direction that is different from the first horizontal direction;
a channel isolation layer on the substrate and in the logic cell region, the channel isolation layer extending in the first horizontal direction and isolating the first active pattern from the second active pattern in the second horizontal direction, wherein sidewalls of the channel isolation layer that are across the second horizontal direction contact the first active pattern and the second active pattern;
a plurality of first sub-nanosheets on the first active pattern and spaced apart from each other in a vertical direction, wherein sidewalls of the plurality of first sub-nanosheets that are across the second horizontal direction contact the channel isolation layer;
a plurality of second sub-nanosheets on the second active pattern and spaced apart from each other in the vertical direction, the plurality of second sub-nanosheets spaced apart from the plurality of first sub-nanosheets in the second horizontal direction, wherein sidewalls of the plurality of second sub-nanosheets that are across the second horizontal direction contact the channel isolation layer;
a gate electrode on the substrate and in the logic cell region, the gate electrode extending in the second horizontal direction and surrounding the plurality of first sub-nanosheets and the plurality of second sub-nanosheets;
a first capping pattern contacting an upper surface of the gate electrode, the first capping pattern extending in the second horizontal direction;
a first alignment gate electrode on the substrate and in the alignment mark region, the first alignment gate electrode extending in a third horizontal direction;
a second alignment gate electrode on the substrate and in the alignment mark region, the second alignment gate electrode extending in the third horizontal direction and spaced apart from the first alignment gate electrode in a fourth horizontal direction that is different from the third horizontal direction;
a first alignment spacer on sidewalls of the first alignment gate electrode that are across the fourth horizontal direction;
a second alignment spacer on sidewalls of the second alignment gate electrode that are across the fourth horizontal direction;
a first alignment capping pattern contacting an upper surface of the first alignment gate electrode, the first alignment capping pattern extending in the third horizontal direction;
a second alignment capping pattern contacting an upper surface of the second alignment gate electrode, the second alignment capping pattern extending in the third horizontal direction, wherein the second alignment capping pattern is spaced apart from the first alignment capping pattern in the fourth horizontal direction;
an alignment trench between the first alignment spacer and the second alignment spacer; and
an alignment insulating structure in the alignment trench,
wherein the alignment insulating structure comprises,
a first layer along sidewalls and a bottom surface of the alignment trench, the first layer contacting the first alignment spacer and the second alignment spacer, wherein a material of the first layer the same as a material of the channel isolation layer, and an upper surface of the first layer is coplanar with an upper surface of the channel isolation layer;
a second layer extending in the vertical direction along inner sidewalls of the first layer, wherein a material of second layer is different from the material of the first layer; and
a third layer filling a remaining portion of the alignment trench, wherein a bottom surface of the third layer contacts the first layer, and a material of the third layer is different from the material of the second layer, and
wherein an upper surface of the first capping pattern, an upper surface of the first alignment capping pattern and an upper surface of the second alignment capping pattern are coplanar with the upper surface of the first layer, an upper surface of the second layer, and an upper surface of the third layer.
